(19) United States
(12) Patent Application Publication
(10) Pub. No.: US 2026/0033058 A1
(43) Pub. Date: Jan. 29, 2026

(54) Display Panel and Method of Manufacturing the Same

(71) Applicant: LG Display Co., Ltd., Seoul (KR)

(72) Inventors: Ye Ji Kim, Paju-si (KR); Eun Min Jo, Paju-si (KR)

(21) Appl. No.: 19/246,680

(22) Filed: Jun. 23, 2025

(30) Foreign Application Priority Data
Jul. 25, 2024 (KR) 10-2024-0098862

(51) Int. Cl. H10H 29/37; H10H 29/34

(52) U.S. Cl. CPC H10H 29/37; H10H 29/34

(57) ABSTRACT

A display panel is disclosed that includes a substrate, a plurality of first banks, a plurality of second banks, and a plurality of third banks disposed on the substrate and spaced apart from each other, a plurality of first light-emitting elements respectively disposed on the first banks and configured to emit light in a first wavelength band, a plurality of second light-emitting elements respectively disposed on the second banks and configured to emit light in a second wavelength band, and a plurality of third light-emitting elements respectively disposed on the third banks and configured to emit light in a third wavelength band, wherein, in at least a partial area of the substrate, a thickness of the substrate between the adjacent banks among the plurality of first banks, the plurality of second banks, and the plurality of third banks is smaller than a thickness of the substrate below the adjacent banks.

### CROSS-REFERENCE TO RELATED APPLICATION

This application claims priority to and the benefit of Republic of Korea Patent Application No. 10-2024-0098862, filed on Jul. 25, 2024, the disclosure of which is incorporated herein by reference in its entirety.

### BACKGROUND

### 1. Field of Technology

The present disclosure relates to a display panel and a method of manufacturing the same.

### 2. Discussion of Related Art

Display devices are being applied to various electronic devices such as televisions (TVs), mobile phones, laptops, and tablets.

Display devices include organic light-emitting display (OLED) devices, which are self-emissive, liquid crystal display (LCD) devices, which require a separate light source, and the like.

In recent years, display devices including light-emitting diodes (LEDs) have been attracting attention as next-generation display devices. Since LEDs are formed of inorganic materials rather than organic materials, the display devices including LEDs have a fast lighting speed and high luminous efficiency, and can display high-brightness images compared to liquid crystal display devices or organic light-emitting display devices.

In transferring inorganic light-emitting elements of a display panel, a multi-place (MP) transfer method may be used, in which the light-emitting elements are picked up from a wafer once and transferred multiple times.

In the multi-place transfer method, the picked-up elements may collide with a substrate or banks of the display panel during transfer, which can cause technical issues such as decreased reliability, and thus, a solution to address this problem is required.

### SUMMARY

The present disclosure is directed to providing a display panel in which process reliability is improved, and a method of manufacturing the same and a display device.

The present disclosure is also directed to providing a display panel in which process reliability and economic efficiency are improved by preventing or at least reducing damage to light-emitting elements during processing, and a method of manufacturing the same and a display device.

Objectives according to embodiments of the present disclosure are not limited to the above-described objectives, and other objectives that are not described herein will be apparently understood by those skilled in the art from the following description.

According to an embodiment of the present disclosure, there is provided a display panel including a plurality of first banks, a plurality of second banks, and a plurality of third banks disposed on a substrate and spaced apart from each other, a plurality of first light-emitting elements respectively disposed on the first banks and configured to emit light in a first wavelength band, a plurality of second light-emitting elements respectively disposed on the second banks and configured to emit light in a second wavelength band, and a plurality of third light-emitting elements respectively disposed on the third banks and configured to emit light in a third wavelength band, wherein, in at least a partial area of the substrate, a thickness of the substrate between the adjacent banks among the plurality of first banks, the plurality of second banks, and the plurality of third banks is smaller than a thickness of the substrate below the adjacent banks.

Specific details according to various examples of the present disclosure other than the means for solving the problems described above are included in the description and drawings below.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is an exploded perspective view of a display device according to an embodiment of the present disclosure;

FIG. 2 is a plan view illustrating the display device according to an embodiment of the present disclosure.

FIG. 3 is an enlarged view illustrating the display device according to an embodiment of the present disclosure;

FIG. 4 is a diagram illustrating a circuit structure according to an embodiment of the present disclosure;

FIG. 5 is a plan view of a wafer according to an embodiment of the present disclosure;

FIGS. 6A to 6C are process views illustrating a method of picking up elements according to an embodiment of the present disclosure;

FIG. 7A is a plan view illustrating a display device according to an embodiment of the present disclosure;

FIG. 7B is a plan view illustrating a display device according to another embodiment of the present disclosure;

FIG. 8 is a plan view illustrating the display device according to an embodiment of the present disclosure;

FIG. 9A is a plan view illustrating the display device according to the embodiment of the present disclosure;

FIG. 9B is a plan view illustrating the display device according to another embodiment of the present disclosure;

FIG. 10A is an enlarged view of a display area including a plurality of pixels according to an embodiment of the present disclosure;

FIG. 10B is an enlarged view of a display area including a plurality of pixels according to another embodiment of the present disclosure;

FIG. 11A is an enlarged view of one pixel (PX) of FIG. 10A according to the embodiment of the present disclosure;

FIG. 11B is an enlarged view of one pixel (PX) of FIG. 10A according to another embodiment of the present disclosure;

FIGS. 12A to 12C are cross-sectional views illustrating a process of transferring light-emitting elements of the display device according to an embodiment of the present disclosure;

FIG. 13 is an enlarged cross-sectional view of a portion of FIG. 12C according to an embodiment of the present disclosure;

FIG. 14 is a cross-sectional view illustrating a process of transferring light-emitting elements of the display device according to another embodiment of the present disclosure;

FIG. 15 is a cross-sectional view of the display device taken along line I-I′ of FIG. 3 according to an embodiment of the present disclosure;

FIG. 16 is a cross-sectional view illustrating a sub-pixel including the light-emitting element disposed in the display area according to an embodiment of the present disclosure;

FIG. 17 is a view illustrating a device to which the display devices according to the embodiments of the present disclosure are applied;

FIG. 18 is a view illustrating a device to which the display devices according to the embodiments of the present disclosure are applied;

FIG. 19 is a view illustrating a device to which the display devices according to the embodiments of the present disclosure are applied; and

FIG. 20 is a view illustrating a device to which the display devices according to the embodiments of the present disclosure are applied.

### DETAILED DESCRIPTION

Advantages and features of the present disclosure and a method of achieving the same should become clear with embodiments described in detail below with reference to the accompanying drawings. However, the present disclosure is not limited to the embodiments described below and may be implemented in various different forms. The embodiments are merely provided to allow those skilled in the art to completely understand the scope of the present disclosure.

The shapes, dimensions, ratios, angles, numbers, and the like disclosed in the drawings for describing the embodiments of the present disclosure are merely illustrative and are not limited to matters shown in the present disclosure. Like reference numerals refer to like elements throughout the specification. Further, in describing the present disclosure, detailed descriptions of well-known technologies will be omitted when it is determined that they may unnecessarily obscure the gist of the present disclosure. Terms such as “including,” “having,” and “composed of” used herein are intended to allow other elements to be added unless the terms are used with the term “only.” Any references to the singular may include the plural unless expressly stated otherwise.

Components are interpreted as including an ordinary error range even if no such margin is explicitly stated.

In the case of a description of a positional relationship, for example, in the case in which a positional relationship between two portions is described with the terms “on,” “above,” “under,” “next to,” or the like, one or more portions may be interposed therebetween unless the term, for example, “right”, “directly”, or “near” is used in the expression.

For the description of a temporal relationship, when a temporal relationship is described as “after,” “subsequently to,” “next,” “before,” and the like, a non-consecutive case may be included unless the term “immediately” or “directly” is used in the expression.

Although the terms “first,” “second,” and the like may be used herein to describe various components, the components are not limited by the terms. These terms are used only to distinguish one component from another. Therefore, a first component described below may be a second component within the technical scope of the present disclosure.

Terms such as first, second, A, B, (a), (b), or the like may be used herein when describing components of the present disclosure. Such terms are used only to distinguish a component from another component, but do not limit the nature, sequence, order, number, or the like of components.

It is to be understood that when a component is described as being “connected,” “coupled,” “linked,” or “attached” to another component, the component may be directly connected, coupled, linked, or attached to the other component, but, unless specifically stated otherwise, still another component may be interposed between the two components so that they are indirectly connected, coupled, linked, or attached.

It is also to be understood that when a component or layer is described as “being in contact with” or “overlapping” another component or layer, the component or layer may be in direct contact with or directly overlapping the other component or layer, but, unless specifically stated otherwise, still another component or layer may be interposed between these two components or layers so that they are in indirect contact with or indirectly overlapping each other.

The term “at least one” should be understood as including any and all combinations of one or more of the associated listed components. For example, the meaning of “at least one of a first component, a second component, and a third component” denotes any combination of two or more of the first component, the second component, and the third component as well as any of the first component, the second component, or the third component.

The terms “first direction,” “second direction,” “third direction,” “X-axis direction,” “Y-axis direction,” and “Z-axis direction” should not be interpreted as referring only to geometrical relationships that are perpendicular to each other, but may indicate a broader range of directions within the functional scope of the configuration described in the present disclosure.

Features of various embodiments of the present disclosure may be partially or fully coupled or combined with each other, and technically, various types of interconnections and driving are possible. The embodiments of the present disclosure may be implemented independently of each other or may be implemented together in a related relationship.

Hereinafter, various embodiments of the present disclosure will be described in detail with reference to the accompanying drawings.

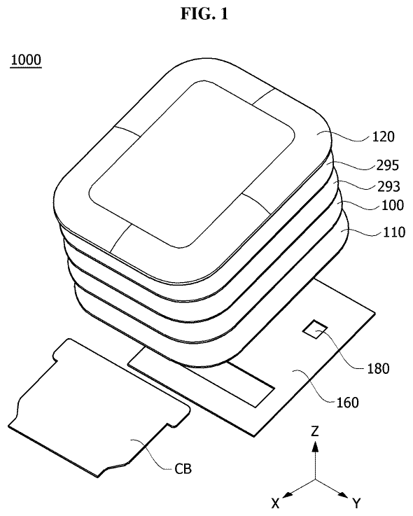

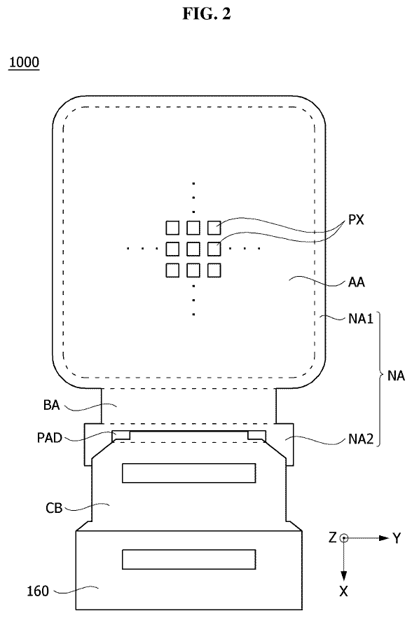

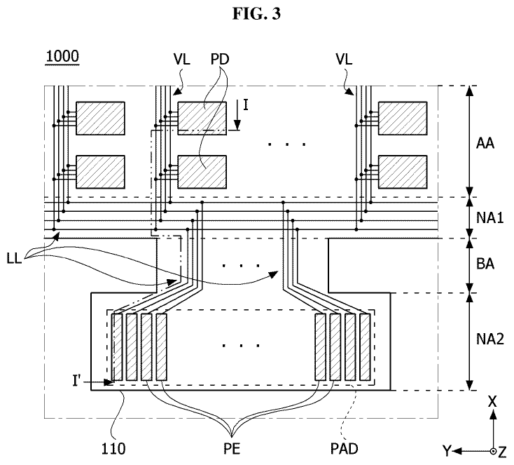

FIG. 1 is an exploded perspective view illustrating a display device according to an embodiment of the present disclosure. FIG. 2 is a plan view illustrating the display device according to an embodiment of the present disclosure. FIG. 3 is an enlarged view illustrating the display device according to an embodiment of the present disclosure.

Referring to FIGS. 1 to 3, a display device 1000 according to an embodiment of the present disclosure may include a display panel 100, a polarizing layer 293, a second adhesive layer 295, a cover member 120, a support substrate 110, a flexible circuit board CB, and a printed circuit board 160.

For example, the display device 1000 may include a support substrate 110. The support substrate 110 may be a member that supports other components of the display device 1000. The support substrate 110 may be formed of an insulating material. For example, the support substrate 110 may be formed of glass, resin, or the like. In addition, the support substrate 110 may be formed of a material that has flexibility. For example, the support substrate 110 may be formed of a plastic material having flexibility, such as polyimide (PI). However, the embodiments of the present disclosure are not limited thereto. Although the drawing shows that the display device 1000 include the display panel 100 and the support substrate 110, however, the support substrate 110 may be treated as a part of the display panel 100.

The display panel 100 may implement information, videos, and/or images provided to a user. For example, the display panel 100 may include a display area AA and a non-display area NA. For example, the support substrate 110 may include the display area AA and the non-display area NA. The display area AA and the non-display area NA are not limited to the support substrate 110 but may be provided throughout the entire display device 1000.

The display area AA may be an area in which an image is displayed. The display area AA may include a plurality of pixels PX. Each of the plurality of pixels PX may be composed of a plurality of sub-pixels. A plurality of light-emitting elements may be disposed in each of the plurality of sub-pixels. The plurality of light-emitting elements may be configured differently depending on the type of the display device 1000. For example, when the display device 1000 is an inorganic light-emitting display device, the light-emitting element may be a light-emitting diode (LED), a micro light-emitting diode (micro LED), or a mini light-emitting diode (mini LED), but the embodiments of the present disclosure are not limited thereto.

The non-display area NA may be an area in which an image is not displayed. Various lines, circuits, and the like for driving the plurality of pixels PX of the display area AA may be disposed in the non-display area NA. For example, in the non-display area NA, various lines and driving circuits may be mounted, and a pad part PAD to which an integrated circuit, a printed circuit, or the like is connected may be disposed, but the embodiments of the present disclosure are not limited thereto.

For example, the driving circuits may be data driving circuits and/or gate driving circuits, but the embodiments of the present disclosure are not limited thereto. Lines through which control signals for controlling the driving circuits are supplied may be disposed on the display panel 100. For example, the control signals may include various timing signals such as clock signals, input data enable signals, and synchronization signals, but the embodiments of the present disclosure are not limited thereto. The control signals may be received through the pad part PAD. For example, link lines LL for transmitting signals may be disposed in the non-display area NA. For example, driving components such as the flexible circuit board CB and the printed circuit board 160 may be connected to the pad part PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1 and may be a bendable area. The second non-display area NA2 may be an area extending from the bending area BA, and the pad part PAD may be disposed therein. For example, the bending area BA may be in a bent state, and the remaining area of the support substrate 110, excluding the bending area BA, may be in a flat state. In this case, as the bending area BA is bent, the second non-display area NA2 may be located on a rear surface of the display area AA. However, the embodiments of the present disclosure are not limited thereto.

The display area AA of the support substrate 110 or the display device 1000 may be configured in various shapes depending on the design of the display device 1000. For example, the display area AA may be configured in a rectangular shape with four rounded corners, but the embodiments of the present disclosure are not limited thereto. In another example, the display area AA may be configured in a rectangular shape with four right-angled corners, a circular shape, or the like, but the embodiments of the present disclosure are not limited thereto.

According to the present disclosure, a width of the second non-display area NA2, in which a plurality of pad electrodes PE are disposed, may be greater than a width of the bending area BA, in which the plurality of link lines LL are disposed. In addition, a width of the display area AA in which the plurality of sub-pixels are disposed may be greater than the width of the bending area BA in which only the plurality of link lines LL are disposed. In the drawings, the width of the bending area BA is illustrated as being smaller than that of each of the other areas of the support substrate 110, but the shape of the support substrate 110 including the bending area BA is exemplary, and the embodiments of the present disclosure are not limited thereto.

Referring to FIG. 3, a plurality of pixel driving circuits PD may be disposed in the display area AA. The plurality of pixel driving circuits PD may be circuits for driving the light-emitting elements of the plurality of sub-pixels. Each of the plurality of pixel driving circuits PD includes a plurality of transistors, including driving transistors, a storage capacitor, and the like, and the pixel driving circuits PD may supply control signals, power, and driving current to the light-emitting elements of the plurality of sub-pixels, thereby controlling the light-emission operations of the plurality of light-emitting elements. For example, the pixel driving circuit PD may include power lines and signal lines for controlling an on/off state and/or a light-emission time of the light-emitting element. For example, the plurality of pixel driving circuits PD may be driving drivers fabricated using a metal-oxide-silicon field-effect transistor (MOSFET) manufacturing process on a semiconductor substrate, but the embodiments of the present disclosure are not limited thereto. The driving drivers include the plurality of pixel driving circuits PD and may drive the plurality of sub-pixels.

Referring to FIG. 1 together, the flexible circuit board CB and the printed circuit board 160 may be disposed below the display panel 100. The flexible circuit board CB and the printed circuit board 160 may be disposed at least one side edge of the display panel 100, but the embodiments of the present disclosure are not limited thereto. One side of the flexible circuit board CB may be attached to the display panel 100, and the other side thereof may be attached to the printed circuit board 160, but the embodiments of the present disclosure are not limited thereto. The flexible circuit board CB may be a flexible film, but the embodiments of the present disclosure are not limited thereto.

The pad part PAD including the plurality of pad electrodes PE may be disposed in the second non-display area NA2. The driving components, including one or more flexible circuit boards (or flexible films) CB and the printed circuit board 160, may be attached or bonded to the pad part PAD. The plurality of pad electrodes PE of the pad part PAD are electrically connected to one or more flexible circuit boards (or flexible films) CB and may transmit various signals (or power) output from the printed circuit board 160 and the flexible circuit boards (or flexible films) CB to the plurality of pixel driving circuits PD in the display area AA.

The flexible circuit board (or flexible film) CB may be a film in which various components are disposed on a base film having flexibility. For example, a driving integrated circuit (IC) such as a gate driver IC or a data driver IC may be disposed on the flexible circuit board (or flexible film) CB, but the embodiments of the present disclosure are not limited thereto. The driving IC may be a component that processes data and driving signals for displaying images. The driving IC may be disposed using methods such as chip on glass (COG), chip on film (COF), or tape carrier package (TCP) depending on a mounting method, but the embodiments of the present disclosure are not limited thereto. The flexible circuit board (or flexible film) CB may be attached or bonded onto the plurality of pad electrodes PE through a conductive adhesive layer, but the embodiments of the present disclosure are not limited thereto.

The printed circuit board 160 may be a component that is electrically connected to one or more flexible circuit boards (or flexible films) and supplies signals to the driving IC. The printed circuit board 160 may be disposed on one side of the flexible circuit board (or flexible film) CB and may be electrically connected to the flexible circuit board (or flexible film) CB. Various components for supplying various signals to the driving IC may be disposed on the printed circuit board 160. For example, various components such as a timing controller, a power supply part, a memory, or a processor may be disposed on the printed circuit board 160. For example, the printed circuit board 160 may include a power management integrated circuit (PMIC), but the embodiments of the present disclosure are not limited thereto.

The printed circuit board 160 may include at least one hole 180, but the embodiments of the present disclosure are not limited thereto. An internal component configured to detect ambient light or temperature, which may be provided to a plurality of sensors, may be disposed in an area corresponding to the at least one hole 180. For example, the internal component may include an ambient light sensor (ALS), a temperature sensor, or the like, but the embodiments of the present disclosure are not limited thereto. For example, the hole 180 may be a through hole or the like, but the embodiments of the present disclosure are not limited thereto.

Referring to FIG. 1, the polarizing layer 293 may be disposed on the display panel 100. The polarizing layer 293 may prevent or reduce the light generated from an external light source from entering the display panel 100 and affecting the light-emitting elements or the like.

The cover member 120 may be disposed on the polarizing layer 293. The cover member 120 may be a member for protecting the display panel 100. The second adhesive layer 295 may be disposed between the polarizing layer 293 and the cover member 120. The cover member 120 may be attached to the display panel 100 by the second adhesive layer 295. The second adhesive layer 295 may include an optically clear adhesive (OCA), an optically clear resin (OCR), a pressure-sensitive adhesive (PSA), or the like, but the embodiments of the present disclosure are not limited thereto.

The support substrate 110 may be disposed between the display panel 100 and the printed circuit board 160. The support substrate 110 may reinforce the rigidity of the display panel 100. The support substrate 110 may be a back plate, but the embodiments of the present disclosure are not limited thereto.

In the non-display area NA, the plurality of link lines LL may be disposed. The plurality of link lines LL may be lines that transmit various signals supplied from one or more flexible circuit boards (or flexible films) CB and the printed circuit board 160 to the display area AA. The plurality of link lines LL may extend from the plurality of pad electrodes PE in the second non-display area NA2 toward the bending area BA and the first non-display area NA1 and may be electrically connected to a plurality of driving lines VL in the display area AA. The plurality of pixel driving circuits PD may be driven by receiving signals from one or more flexible circuit boards (or flexible films) CB and the printed circuit board 160 through the driving lines VL in the display area AA and the link lines LL in the non-display area NA.

For example, the plurality of driving lines VL, along with the plurality of link lines LL, may serve as lines for transmitting signals output from the flexible circuit board (or flexible film) CB and the printed circuit board 160 to the plurality of pixel driving circuits PD. The plurality of driving lines VL may be disposed in the display area AA and electrically connected to the plurality of pixel driving circuits PD, respectively. The plurality of driving lines VL may extend from the display area AA toward the non-display area NA to be electrically connected to the plurality of link lines LL. Accordingly, the signals output from the flexible circuit board (or flexible film) CB and the printed circuit board 160 may be transmitted to each of the plurality of pixel driving circuits PD through the plurality of link lines LL and the plurality of driving lines VL.

As the bending area BA is bent, some of the plurality of link lines LL may also be bent. Stress may be concentrated on a portion of the bent link lines LL, and as a result, cracks may occur in the link lines LL. Accordingly, the plurality of link lines LL may be formed of a conductive material with excellent flexibility to reduce cracks during the bending of the bending area BA. For example, the plurality of link lines LL may be formed of a conductive material with excellent flexibility such as gold (Au), silver (Ag), or aluminum (Al), but the embodiments of the present disclosure are not limited thereto. In addition, the plurality of link lines LL may be formed of one of various conductive materials used in the display area AA. For example, the plurality of link lines LL may be formed of molybdenum (Mo), chromium (Cr), titanium (Ti), nickel (Ni), neodymium (Nd), copper (Cu), silver (Ag), magnesium (Mg), or alloys thereof, but the embodiments of the present disclosure are not limited thereto. The plurality of link lines LL may be configured in a multilayer structure including various conductive materials. For example, the plurality of link lines LL may be configured in a triple-layer structure of titanium (Ti)/aluminum (Al)/titanium (Ti), but the embodiments of the present disclosure are not limited thereto.

The plurality of link lines LL may be configured in various shapes to reduce stress. At least some of the plurality of link lines LL disposed in the bending area BA may extend in the same direction as an extension direction of the bending area BA or extend in a direction different from the extension direction of the bending area BA to reduce stress. For example, when the bending area BA extends in one direction from the first non-display area NA1 toward the second non-display area NA2, at least some of the link lines LL disposed in the bending area BA may extend in a direction oblique to the one direction. In another example, at least some of the plurality of link lines LL may be configured in various pattern shapes. For example, at least some of the plurality of link lines LL disposed in the bending area BA may have a conductive pattern repetitively disposed in at least one shape among a diamond shape, a rhombus shape, a trapezoidal wave shape, a triangular wave shape, a sawtooth wave shape, a sine wave shape, a circular shape, and an omega (Ω) shape, but the embodiments of the present disclosure are not limited thereto. Accordingly, to minimize the stress concentrated on the plurality of link lines LL and the resulting cracks, the plurality of link lines LL may be formed in various shapes including the above-described shapes, but the embodiments of the present disclosure are not limited thereto.

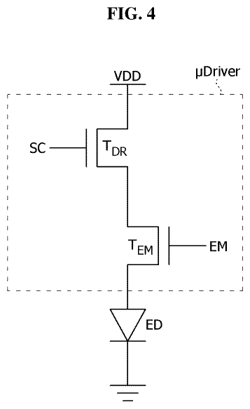

FIG. 4 is a diagram illustrating a circuit structure according to an embodiment of the present disclosure;

Referring to FIG. 4, an example is illustrated in which one light-emitting element ED is connected to a micro driver μDriver, but the present disclosure is not limited thereto. For example, eight light-emitting elements ED may be connected to one micro driver μDriver. In another example, 16 light-emitting elements ED may be connected to one micro driver μDriver, or 32 light-emitting elements ED or 64 light-emitting elements ED may be simultaneously connected to one micro driver μDriver. The light-emitting element ED may be a micro light-emitting element (μLED).

One micro driver μDriver may include a driving transistor T_{DR} and a light-emitting transistor T_{EM}, but the embodiments of the present disclosure are not limited thereto.

For example, the driving transistor T_{DR} has a first electrode to which a high-potential power supply voltage VDD may be applied, a second electrode to which a first electrode of the light-emitting transistor T_{EM} may be connected, and a gate electrode to which a scan signal SC may be applied. The scan signal SC applied to the gate electrode of the driving transistor T_{DR} may be direct current (DC) power, and a fixed reference voltage Vref may be applied for each frame, but the embodiments of the present disclosure are not limited thereto.

The light-emitting transistor T_{EM} has the first electrode to which the second electrode of the driving transistor T_{DR} may be connected, a second electrode to which the light-emitting element ED may be connected, and a gate electrode to which a light-emission signal EM may be applied. The light-emission signal EM applied to the gate electrode of the light-emitting transistor T_{EM} may be a pulse width modulation (PWM) signal that varies for each frame, but the embodiments of the present disclosure are not limited thereto.

A first electrode of the light-emitting element ED may be connected to the second electrode of the light-emitting transistor T_{EM}, and a second electrode of the light-emitting element ED may be connected to the ground. For example, the first electrode of the light-emitting element ED may be an anode, and the second electrode of the light-emitting element ED may be a cathode, but the embodiments of the present disclosure are not limited thereto.

The driving transistor T_{DR} and the light-emitting transistor T_{EM} may each be an n-type transistor or a p-type transistor.

In the micro driver μDriver, the driving transistor T_{DR} may be turned on by the scan signal SC applied from a timing controller (T-CON), and the light-emitting transistor T_{EM} may be turned on by the light-emission signal EM. As a result, a driving current may be applied to the light-emitting element ED via the driving transistor T_{DR} and the light-emitting transistor T_{EM} by the high-potential power supply voltage VDD applied to the first electrode of the driving transistor T_{DR}, thereby enabling the light-emitting element ED to emit light.

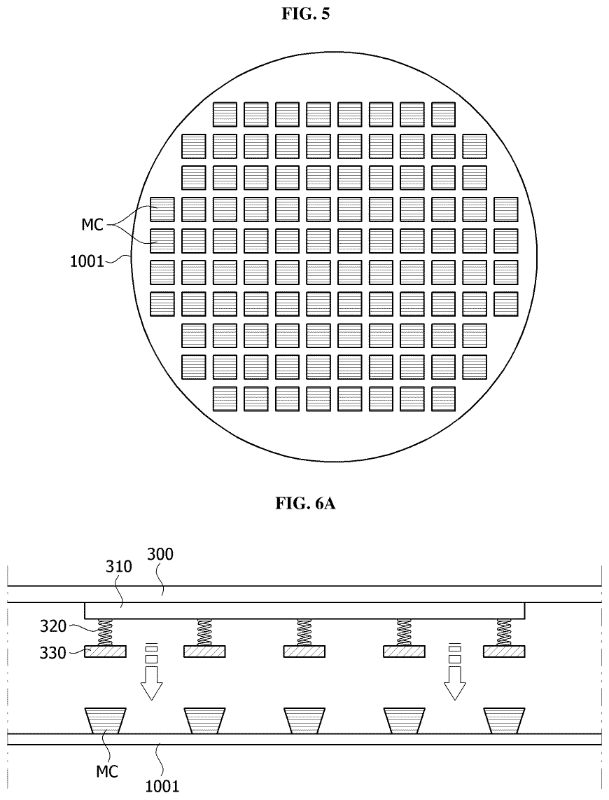

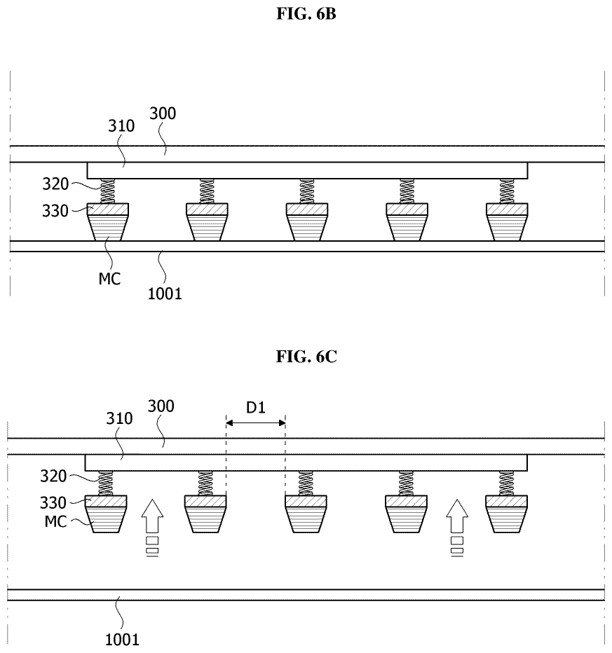

FIG. 5 is a plan view of a wafer according to an embodiment of the present disclosure. FIGS. 6A to 6C are process views illustrating a method of picking up light-emitting elements according to an embodiment of the present disclosure.

Referring to FIGS. 5 and 6A to 6C, elements MC disposed on a wafer 1001 may be inorganic light-emitting elements. When inorganic light-emitting elements are used as the light-emitting elements ED, the elements MC may be transferred using a multi-place (MP) process, in which a plurality of inorganic light-emitting elements of the same color are simultaneously picked up from a semiconductor substrate by adhesion or suction, and only a portion of the picked-up elements are transferred to predetermined banks BNK.

A light-emitting element transfer apparatus may include a transfer substrate 300, a stamp 310 disposed below the transfer substrate 300, pickup heads 330 configured to pick up the elements MC and disposed below the stamp 310, and elastic members 320 each connecting the pickup head 330 and the stamp 310. The pickup heads 330 may pick up the elements MC from the wafer 1001 using an adhesive layer and electrostatic force, or the like.

For example, when transferring the elements MC using a multi-place process, a plurality of elements MC that emit light in a first wavelength band may be simultaneously picked up by being attached to the respective pickup heads 330.

Thereafter, some of the element's MC may be separated from the corresponding pickup heads 330 and transferred to predetermined banks BNK on a support substrate 110, after which the pickup heads may be moved.

By repeating the process of separating others of the elements MC from the corresponding pickup heads 330 and transferring the other elements MC onto the support substrate 110 a total of N times (where N is an integer greater than or equal to 2), the number of times the elements MC are picked up may be reduced compared to a transfer method of transferring the elements MC onto the support substrate 110 once per pickup, thereby increasing a transfer speed.

When picking up the elements MC using an electrostatic force, the elements MC may be picked up by the pickup heads 330 through Van der Waals forces acting at the interfaces between the pickup heads 330 and the elements MC. In addition, the pickup heads 330 for the light-emitting elements may be coated with an adhesive material such as polydimethylsiloxane (PDMS) at lower portions thereof, thereby allowing the elements MC to adhere thereto upon contact. However, the embodiments of the present disclosure are not limited thereto.

The pickup heads 330 may pick up the elements MC while being spaced apart from each other by a predetermined spacing (first spacing) D1. For example, when the elements MC to be picked up are inorganic light-emitting elements, the first spacing D1 between the pickup heads 330 may be approximately 30 to 40 μm.

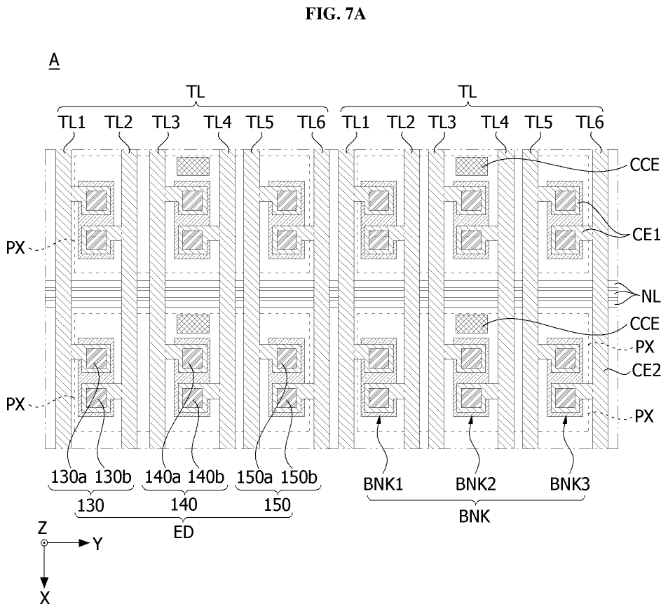

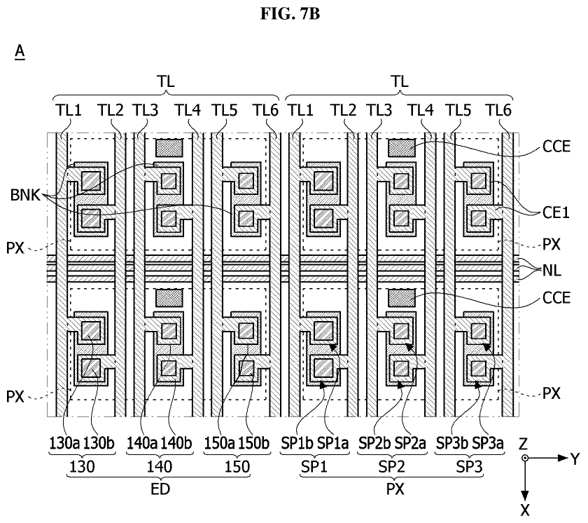

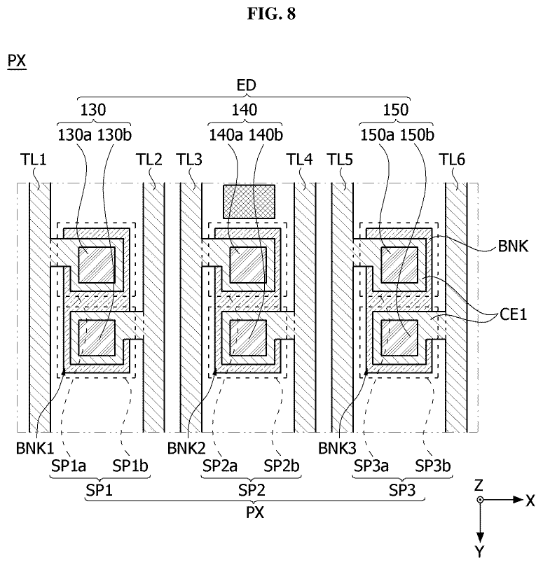

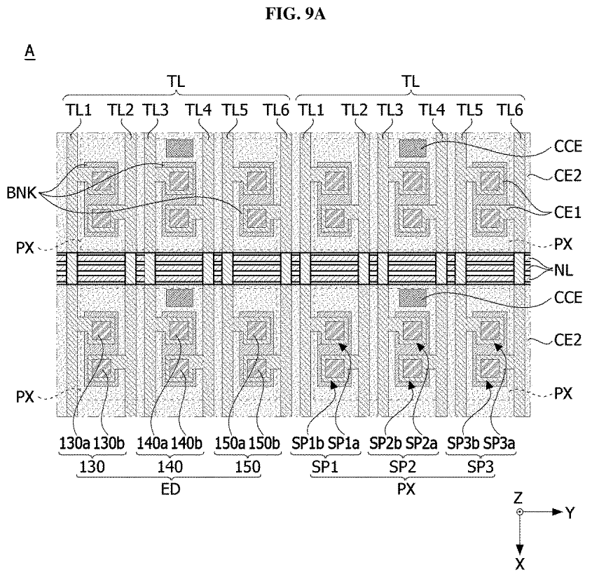

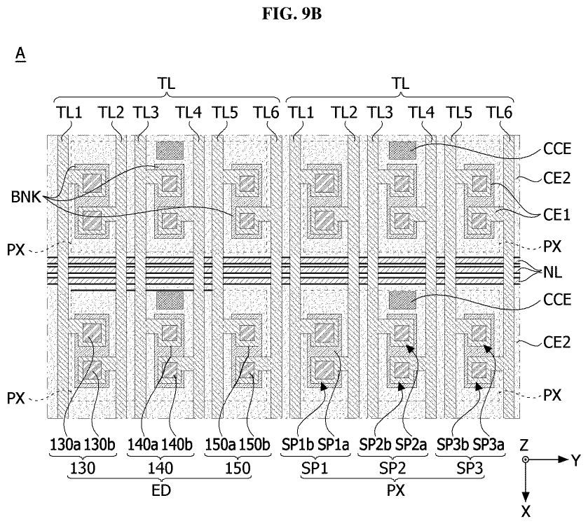

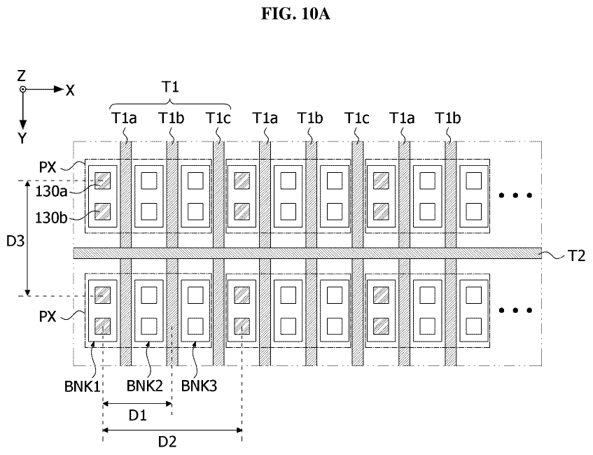

FIG. 7A is an enlarged view of a display area including a plurality of pixels according to one embodiment of the present disclosure. FIG. 7B is a plan view illustrating a display device according to another embodiment of the present disclosure. FIG. 8 is an enlarged view of the display area including one pixel according to one embodiment of the present disclosure. FIG. 8 is a partial enlarged view illustrating one pixel PX of FIG. 7A. FIG. 9A is a plan view illustrating the display device according to an embodiment of the present disclosure. FIG. 9B is a plan view illustrating the display device according to another embodiment of the present disclosure.

FIGS. 7A and 9A illustrate a plurality of signal lines TL, a plurality of communication lines NL, a plurality of first electrodes CE1, a plurality of banks BNK, and a plurality of light-emitting elements ED, but the embodiments of the present disclosure are not limited thereto. FIGS. 9A and 9B are enlarged plan views of FIGS. 7A and 7B, respectively, in which a plurality of second electrodes CE2 are further disposed.

Referring to FIG. 7A, a plurality of pixels PX, each composed of a plurality of sub-pixels, may be disposed in a display area AA. Each of the plurality of sub-pixels may include a light-emitting element ED and may emit light independently. The plurality of sub-pixels may be disposed in a matrix form forming a plurality of rows and a plurality of columns, but the embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another one thereof may be a green sub-pixel, and the remaining one thereof may be a blue sub-pixel. The types of the plurality of sub-pixels are exemplary, and the embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may be composed of a 1-1 sub-pixel SP1a and a 1-2 sub-pixel SP1b. The pair of second sub-pixels SP2 may be composed of a 2-1 sub-pixel SP2a and a 2-2 sub-pixel SP2b. The pair of third sub-pixels SP3 may be composed of a 3-1 sub-pixel SP3a and a 3-2 sub-pixel SP3b. For example, one pixel PX may include the 1-1 sub-pixel SP1a and the 1-2 sub-pixel SP1b, the 2-1 sub-pixel SP2a and the 2-2 sub-pixel SP2b, and the 3-1 sub-pixel SP3a and the 3-2 sub-pixel SP3b, but the embodiments of the present disclosure are not limited thereto.

The plurality of sub-pixels constituting one pixel PX may be arranged in various ways. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of the plurality of sub-pixels constituting one pixel PX are exemplary, and the embodiments of the present disclosure are not limited thereto.

A plurality of signal lines TL may be disposed in areas between the plurality of sub-pixels. The plurality of signal lines TL may extend in a column direction between the plurality of sub-pixels. The plurality of signal lines TL may be lines that transmit an anode voltage output from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels through the plurality of signal lines TL. For example, the first electrode CE1 may be an electrode that is electrically connected to an anode 134 of the light-emitting element ED. Thus, the anode voltage transmitted through the signal line TL may be transmitted to the anode 134 of the light-emitting element ED through the first electrode CE1.

Accordingly, the structure of the display device 1000 may be simplified by using the pixel driving circuit PD, in which a plurality of pixel circuits are integrated, instead of forming a plurality of transistors and a storage capacitor in each of the plurality of sub-pixels. In addition, as the circuits disposed in each of the plurality of sub-pixels are integrated into one pixel driving circuit PD, high-efficiency and low-power operation may be enabled. The integration of circuits respectively disposed in the plurality of sub-pixels SP into one pixel driving circuit PD means that the pixel driving circuit PD includes a plurality of pixel circuits capable of driving the plurality of light-emitting elements ED. The plurality of light-emitting elements ED may be driven by one pixel driving circuit PD in which a plurality of pixel circuits are integrated. For example, a 1-1 light-emitting element 130a, a 2-1 light-emitting element 140a, and a 3-1 light-emitting element 150a may be driven by one pixel driving circuit PD in which a plurality of pixel circuits are integrated.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed on one side of the pair of first sub-pixels SP1, and the second signal line TL2 may be disposed on another side of the pair of first sub-pixels SP1. The first signal line TL1 may be electrically connected to the first electrode CE1 of one of the pair of first sub-pixels SP1, for example, the 1-1 sub-pixel SP1a. The second signal line TL2 may be electrically connected to the first electrode CE1 of the other of the pair of first sub-pixels SP1, for example, the 1-2 sub-pixel SP1b.

The third signal line TL3 may be disposed on one side of the pair of second sub-pixels SP2, and the fourth signal line TL4 may be disposed on another side of the pair of second sub-pixels SP2. For example, the third signal line TL3 may be disposed adjacent to the second signal line TL2. The third signal line TL3 may be electrically connected to the first electrode CE1 of one of the pair of second sub-pixels SP2, for example, the 2-1 sub-pixel SP2a. The fourth signal line TL4 may be electrically connected to the first electrode CEL of the other of the pair of second sub-pixels SP2, for example, the 2-2 sub-pixel SP2b.

The fifth signal line TL5 may be disposed on one side of the pair of third sub-pixels SP3, and the sixth signal line TL6 may be disposed on another side of the pair of third sub-pixels SP3. For example, the fifth signal line TL5 may be disposed adjacent to the fourth signal line TLA. The sixth signal line TL6 may be disposed adjacent to the first signal line TL1 connected to the neighboring pixel PX. The fifth signal line TL5 may be electrically connected to the first electrode CE1 of one of the pair of third sub-pixels SP3, for example, the 3-1 sub-pixel SP3a. The sixth signal line TL6 may be electrically connected to the first electrode CE1 of the other of the pair of third sub-pixels SP3, for example, the 3-2 sub-pixel SP3b.

The plurality of signal lines TL may be formed of a conductive material. For example, the plurality of signal lines TL may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. In another example, the plurality of signal lines TL may be formed in a multilayer structure of conductive materials. For example, the plurality of signal lines TL may be formed in a multilayer structure of titanium (Ti)/aluminum (Al)/titanium (Ti)/indium tin oxide (ITO), but the embodiments of the present disclosure are not limited thereto.

The plurality of communication lines NL may be disposed in areas between the plurality of pixels PX. The plurality of communication lines NL may be disposed to extend in a row direction in the areas between the plurality of pixels PX. For example, the plurality of communication lines NL may be lines used for short-range communication, such as near-field communication (NFC). The plurality of communication lines NL may function as antennas. For example, the plurality of communication lines NL may be a plurality of connection lines or the like, but the embodiments of the present disclosure are not limited thereto.

According to the present disclosure, a bank BNK may be disposed in each of the plurality of sub-pixels. The plurality of banks BNK may be structures on which the plurality of light-emitting elements ED are mounted. The plurality of banks BNK may guide positions of the plurality of light-emitting elements ED in a transfer process of transferring the plurality of light-emitting elements ED to the display device 1000. In the transfer process of the plurality of light-emitting elements ED, the plurality of light-emitting elements ED may be transferred onto the plurality of banks BNK. The plurality of banks BNKs may be bank patterns or structures, but the embodiments of the present disclosure are not limited thereto.

A bank BNK of the first sub-pixel SP1, a bank BNK of the second sub-pixel SP2, and a bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be configured to be separated from each other. Thus, the banks BNK of the first sub-pixel SP1, the second sub-pixel SP2, and the third sub-pixel SP3, onto which different types of light-emitting elements ED are transferred, may be easily identified.

A bank BNK of the 1-1 sub-pixel SP1a and a bank BNK of the 1-2 sub-pixel SP1b may be connected to each other or may be spaced apart from each other or separately formed. For example, considering the design requirements of the transfer process and the like, the bank BNK of the 1-1 sub-pixel SP1a and the bank BNK of the 1-2 sub-pixel SP1b, in which the same type of light-emitting elements ED are disposed, may be connected to each other, or may be spaced apart or separated from each other. In addition, a bank BNK of the 2-1 sub-pixel SP2a and a bank BNK of the 2-2 sub-pixel SP2b may be connected to each other or may be spaced apart from each other or separately formed. A bank BNK of the 3-1 sub-pixel SP3a and a bank BNK of the 3-2 sub-pixel SP3b may be connected to each other or may be spaced apart from each other or separately formed. Accordingly, the banks BNK of the pair of first sub-pixels SP1, the banks BNK of the pair of second sub-pixels SP2, and the banks BNK of the pair of third sub-pixels SP3 may be variously formed, but the embodiments of the present disclosure are not limited thereto.

For example, the plurality of banks BNK may be formed of an organic insulating material. The plurality of banks BNK may be formed of a single layer or multiple layers of an organic insulating material. For example, the plurality of banks BNK may be formed of a photoresist, a polyimide (PI)-based material, a photo acrylic-based material, or the like, but the embodiments of the present disclosure are not limited thereto.

The first electrode CE1 may be disposed in each of the plurality of sub-pixels. The first electrode CE1 may be disposed on the bank BNK. The first electrode CE1 may be electrically connected to one of the plurality of signal lines TL. At least a portion of the first electrode CE1 may extend outward from the bank BNK to be electrically connected to the signal line TL closest to the first electrode CE1. For example, a portion of the first electrode CE1 of the 1-1 sub-pixel SP1a may extend to one side area of the 1-1 sub-pixel SP1a to be electrically connected to the first signal line TL1, and a portion of the first electrode CE1 of the 1-2 sub-pixel SP1b may extend to the other side area of the 1-2 sub-pixel SP1b to be electrically connected to the second signal line TL2. A portion of the first electrode CE1 of the 2-1 sub-pixel SP2a may extend to one side area of the 2-1 sub-pixel SP2a to be electrically connected to the third signal line TL3, and a portion of the first electrode CE1 of the 2-2 sub-pixel SP2b may extend to the other side area of the 2-2 sub-pixel SP2b to be electrically connected to the fourth signal line TL4. A portion of the first electrode CE1 of the 3-1 sub-pixel SP3a may extend to one side area of the 3-1 sub-pixel SP3a to be electrically connected to the fifth signal line TL5, and a portion of the first electrode CE1 of the 3-2 sub-pixel SP3b may extend to the other side area of the 3-2 sub-pixel SP3b to be electrically connected to the sixth signal line TL6.

The first electrode CE1 may be electrically connected to the anode 134 of the light-emitting element ED, and may transmit the anode voltage output from the pixel driving circuit PD to the light-emitting element ED through the signal line TL. Different voltages may be applied to the first electrode CE1 of each of the plurality of sub-pixels depending on the displayed image. For example, different voltages may be applied to the first electrode CE1 of each of the plurality of sub-pixels. Accordingly, the first electrode CE1 may be a pixel electrode, but the embodiments of the present disclosure are not limited thereto.

The first electrode CE1 may be formed of a conductive material. For example, the first electrodes CE1 may be configured integrally with the plurality of signal lines TL. For example, the first electrodes CE1 may be formed of the same conductive material as the plurality of signal lines TL, but the embodiments of the present disclosure are not limited thereto. For example, the first electrode CE1 may be formed of a conductive material such as titanium (Ti), aluminum (Al), copper (Cu), molybdenum (Mo), nickel (Ni), chromium (Cr), indium tin oxide (ITO), indium zinc oxide (IZO), or indium gallium zinc oxide (IGZO), but the embodiments of the present disclosure are not limited thereto. In another example, the first electrode CE1 may be formed in a multilayer structure of conductive materials. For example, the plurality of first electrodes CE1 may be formed in a multilayer structure of titanium (Ti)/aluminum (Al)/titanium (Ti)/indium tin oxide (ITO), but the embodiments of the present disclosure are not limited thereto.

The light-emitting element ED may be disposed in each of the plurality of sub-pixels. Each of the plurality of light-emitting elements ED may be either a light-emitting diode (LED) or a micro light-emitting diode (micro LED), but the embodiments of the present disclosure are not limited thereto. The plurality of light-emitting elements ED may be disposed on the banks BNK and the first electrodes CE1. The plurality of light-emitting elements ED may be disposed on the first electrodes CE1 and may be electrically connected to the first electrodes CE1. Thus, the light-emitting element ED may emit light by receiving the anode voltage from the pixel driving circuit PD through the signal line TL and the first electrode CE1.

The plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another one thereof may be a green light-emitting element, and the remaining one thereof may be a blue light-emitting element, but the embodiments of the present disclosure are not limited thereto. Accordingly, by combining red light, green light, and blue light emitted from the plurality of light-emitting elements ED, various colors of light including white may be implemented. The types of the plurality of light-emitting elements ED are exemplary, and the embodiments of the present disclosure are not limited thereto.

The first light-emitting element 130 may include the 1-1 light-emitting element 130a disposed in the 1-1 sub-pixel SP1a and a 1-2 light-emitting element 130b disposed in the 1-2 sub-pixel SP1b. The second light-emitting element 140 may include the 2-1 light-emitting element 140a disposed in the 2-1 sub-pixel SP2a and a 2-2 light-emitting element 140b disposed in the 2-2 sub-pixel SP2b. The third light-emitting element 150 may include the 3-1 light-emitting element 150a disposed in the 3-1 sub-pixel SP3a and a 3-2 light-emitting element 150b disposed in the 3-2 sub-pixel SP3b.

Referring to FIGS. 9A and 9B, the second electrode CE2 may be disposed in each of the plurality of sub-pixels. The second electrode CE2 may be disposed on the light-emitting element ED. The second electrodes CE2 may be electrically connected to the pixel driving circuit PD through a plurality of contact electrodes CCE.

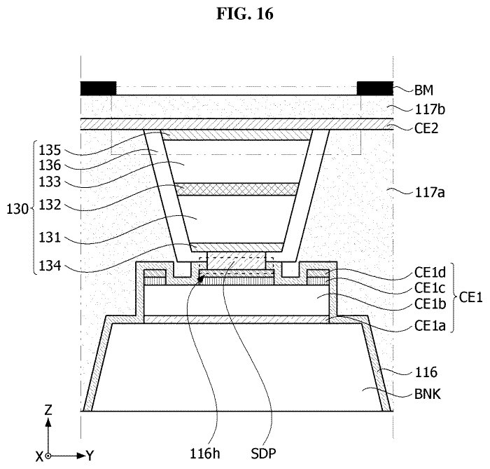

For example, the second electrode CE2 may be electrically connected to a cathode 135 show in FIG. 16 of the light-emitting element ED, and may transmit a cathode voltage output from the pixel driving circuit PD to the light-emitting element ED. The same cathode voltage may be applied to the second electrode CE2 of each of the plurality of sub-pixels. For example, the same voltage may be applied to the second electrodes CE2 of the plurality of sub-pixels and the cathode 135 of the light-emitting element ED. Accordingly, the second electrode CE2 may be a common electrode, but the embodiments of the present disclosure are not limited thereto.

At least some of the plurality of sub-pixels may share the second electrode CE2. At least some of the second electrodes CE2 of the plurality of sub-pixels may be electrically connected to each other. Since the same voltage is applied to the second electrodes CE2, the second electrodes CE2 of at least some of the sub-pixels may be shared and used. For example, the second electrodes CE2 of at least some of the plurality of pixels PX disposed in the same row may be connected to each other. For example, one second electrode CE2 may be disposed in the plurality of pixels PX. One second electrode CE2 may be disposed for every n sub-pixels.

For example, some of the second electrodes CE2 of the plurality of sub-pixels may be spaced apart from each other or separately disposed. For example, the second electrodes CE2 connected to the pixels PX in an nth row and the second electrodes CE2 connected to the pixels PX in an (n+1)th row may be spaced apart from each other or separately disposed. For example, the plurality of second electrodes CE2 may be disposed to be spaced apart from each other with the plurality of communication lines NL extending in the row direction interposed therebetween. The plurality of communication lines NL are disposed in areas between the plurality of second electrodes CE2 and may not overlap the plurality of second electrodes CE2. Accordingly, the number of sub-pixels may be greater than the number of second electrodes CE2. In another example, all of the second electrodes CE2 of the plurality of sub-pixels may be interconnected so that only one second electrode CE2 is disposed on the support substrate 110, but the embodiments of the present disclosure are not limited thereto.

The plurality of second electrodes CE2 may be formed of a transparent conductive material, but the embodiments of the present disclosure are not limited thereto. The plurality of second electrodes CE2 may be formed of a transparent conductive material so that light emitted from the light-emitting elements ED is directed upward through the second electrodes CE2. For example, the second electrode CE2 may be formed of a transparent conductive material such as indium tin oxide (ITO), indium zinc oxide (IZO), or indium gallium zinc oxide (IGZO), but the embodiments of the present disclosure are not limited thereto.

A plurality of contact electrodes CCE may be disposed on the support substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the support substrate 110 and the plurality of second electrodes CE2 and may transmit the cathode voltage output from the pixel driving circuit PD to the second electrodes CE2.

For example, when micro LEDs are used as the light-emitting elements ED, a plurality of micro LEDs may be formed on a wafer and transferred onto the support substrate 110 of the display device 1000 to manufacture the display device 1000. During the process of transferring the plurality of light-emitting elements ED having a micro size from the wafer to the support substrate 110, various defects may occur. For example, in some sub-pixels, a transfer defect may occur in which the light-emitting element ED is not transferred, and in other sub-pixels, a defect may occur in which the light-emitting element ED is transferred out of an intended position due to misalignment. In addition, although the transfer process proceeds normally, the transferred light-emitting element ED itself may be defective. Thus, in consideration of the defects that may occur during the transfer of the plurality of light-emitting elements ED, the plurality of light-emitting elements ED of the same type may be transferred onto one sub-pixel. A lighting test may be performed on the plurality of light-emitting elements ED, and ultimately, only one light-emitting element ED that is determined to be normal may be used.

For example, the 1-1 light-emitting element 130a and the 1-2 light-emitting element 130b may be transferred together onto one pixel PX, and may be inspected to determine whether there is a defect. When both the 1-1 light-emitting element 130a and the 1-2 light-emitting element 130b are determined to be normal, the 1-1 light-emitting element 130a may be used, and the 1-2 light-emitting element 130b may not be used. In another example, when the 1-2 light-emitting element 130b among the 1-1 light-emitting element 130a and the 1-2 light-emitting element 130b is determined to be normal, the 1-1 light-emitting element 130a may not be used, and the 1-2 light-emitting element 130b may be used. Accordingly, even when the plurality of light-emitting elements ED of the same type are transferred onto one pixel PX, ultimately, only one light-emitting element ED may be used.

Thus, one of the pair of light-emitting elements ED may be a main (or primary) light-emitting element ED, and the other one thereof may be a redundancy light-emitting element ED. The redundancy light-emitting element ED may be a spare light-emitting element ED transferred in preparation for a defective main light-emitting element ED. In the event of a defective main light-emitting element ED, the redundancy light-emitting element ED may be used as a replacement. Accordingly, by transferring both the main light-emitting element ED and the redundancy light-emitting element ED onto one pixel PX, the degradation of display quality due to the failure of the main light-emitting element ED or the redundancy light-emitting element ED may be minimized.

For example, the 1-1 light-emitting element 130a, the 2-1 light-emitting element 140a, and the 3-1 light-emitting element 150a transferred onto one pixel PX may be used as main light-emitting elements ED, and the 1-2 light-emitting element 130b, the 2-2 light-emitting element 140b, and the 3-2 light-emitting element 150b transferred onto one pixel PX may be used as redundancy light-emitting elements ED.

A plurality of light-emitting elements 130, 140, and 150 disposed in the display area AA may include the first light-emitting elements 130, the second light-emitting elements 140, and the third light-emitting elements 150. The first light-emitting elements 130, the second light-emitting elements 140, and the third light-emitting elements 150 may respectively implement light in a first wavelength band, a second wavelength band, and a third wavelength band. The light in each of the first to third wavelength bands may be one selected from red, green, and blue so as not to overlap with each other, but the embodiments of the present disclosure are not limited thereto. For example, the light in the first wavelength band may be red, the light in the second wavelength band may be green, and the light in the third wavelength band may be blue, but the present disclosure is not limited thereto.

Referring to FIGS. 7B and 9B, at least one of the banks BNK, on which the plurality of light-emitting elements 130, 140, and 150 are disposed, may have a size different from that of the others. For example, the plurality of banks BNK on which the first light-emitting elements 130 are disposed may have a greater size than the plurality of banks BNK on which the second and third light-emitting elements 140 and 150 are disposed. In addition, the first light-emitting element 130 may have a greater size than the other light-emitting elements 140 and 150. The second light-emitting element 140 and the third light-emitting element 150 may have substantially the same size, but the present disclosure is not limited thereto.

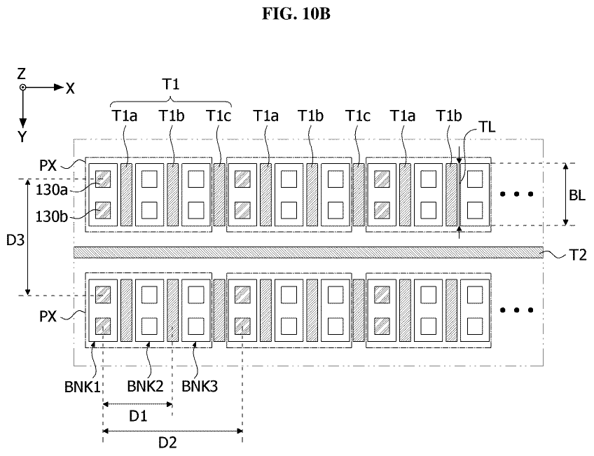

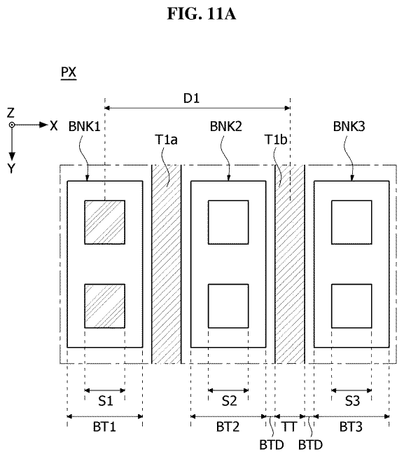

FIG. 10A is an enlarged view of a display area including a plurality of pixels according to an embodiment of the present disclosure.

FIG. 10B is an enlarged view of a display area including a plurality of pixels according to another embodiment of the present disclosure.

Referring to FIGS. 10A and 10B, each of a plurality of pixels PX may include one or more first light-emitting elements 130, one or more second light-emitting elements 140, and one or more third light-emitting elements 150. As for the first light-emitting elements, a 1-1 light-emitting element 130a and a 1-2 light-emitting element 130b may be transferred onto one first bank BNK1. Trenches T1 and T2 may be disposed between adjacent banks BNK1, BNK2, and BNK3, on which the plurality of light-emitting elements 130, 140, and 150 are respectively disposed. The first trenches T1 have widths that may be different depending on the light-emitting elements 130, 140, and 150 disposed on the adjacent banks BNK1, BNK2 and BNK3.

A 1-1 trench T1a may be disposed between the first bank BNK1 and a second bank BNK2, which are adjacent to each other in a first direction (e.g., an X-axis direction), within the same pixel PX, a 1-2 trench T1b may be disposed between the second bank BNK2 and a third bank BNK3, which are adjacent to each other in the first direction, and a 1-3 trench T1c may be disposed between the third bank BNK3 and the first bank BNK1 of the adjacent pixel PX. Each of the first trenches T1a, T1b, and T1c may be disposed to extend in a second direction (e.g., a Y-axis direction).

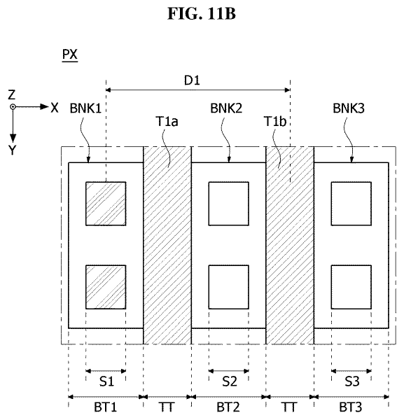

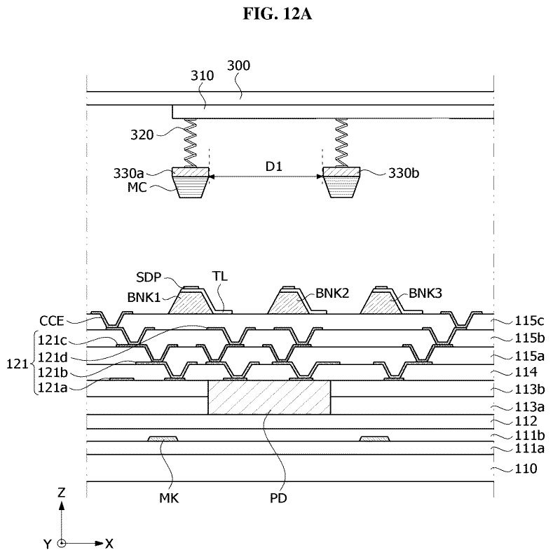

A second trench T2 may be disposed between the first banks BNK1 adjacent in the second direction, between the second banks BNK2 adjacent in the second direction, and between the third banks BNK3 adjacent in the second direction. As shown in FIG. 11A and FIG. 11B, each of the second trenches T2 has a second length smaller than a length of each of the adjacent banks BNK1, BNK2 and BNK3 in the Y-axis direction.

The first trench T1 and the second trench T2 may be disposed to overlap each other while being orthogonal to each other in the first and second directions.

A second spacing D2 between the first light-emitting element 130 disposed in one pixel PX and the first light-emitting element 130 disposed in a pixel PX adjacent thereto in the first direction, and a third spacing D3 between the first light-emitting element 130 disposed in one pixel PX and the first light-emitting element 130 disposed in a pixel PX adjacent in the second direction, may each be formed to be greater than the first spacing D1 between the pickup heads 330 that transfer the first light-emitting elements 130. The second spacing D2 and the third spacing D3 may be formed to be substantially the same.

Referring to FIG. 10B, the trenches T1a, T1b, and T1c, which are disposed between the banks BNK1, BNK2, and BNK3 adjacent to each other in the first direction, may not extend in the second direction but may be disposed to have the same length as a length BL of the banks BNK in the second direction.

FIG. 11A is an enlarged view of one pixel PX of FIG. 10A according to an embodiment of the present disclosure. FIG. 11B is an enlarged view of one pixel PX of FIG. 10A according to another embodiment of the present disclosure.

Referring to FIGS. 11A and 11B, a length BT1 of the first bank BNK1 in the first direction, a length BT2 of the second bank BNK2 in the first direction, and a length BT3 of the third bank BNK3 in the first direction may be configured to be the same, but the present disclosure is not limited thereto. For example, the length BT1 of the first bank BNK1 in the first direction may be configured to be greater than the lengths BT2 and BT3 of the second and third banks BNK2 and BNK3 in the first direction. In this case, the lengths BT2 and BT3 of the second and third banks BNK2 and BNK3 in the first direction may be configured to be substantially the same.

Referring to FIGS. 7B and 9B again, at least one of a size S1 of the first light-emitting element 130 disposed on the first bank BNK1, a size S2 of the second light-emitting element 140 disposed on the second bank BNK2, and a size S3 of the third light-emitting element 150 disposed on the third bank BNK3 may be configured to have a different size from the other light-emitting elements. For example, the size S1 of the first light-emitting element 130 may be formed to be greater than the sizes S2 and S3 of the other light-emitting elements 140 and 150.

The first spacing D1 between the pickup heads 330 that transfer the first light-emitting elements 130 may be the same as a distance between the first light-emitting element 130 and the 1-2 trench T1b. By making the first spacing D1 between the pickup heads 330 that transfer the first light-emitting elements 130 equal to the distance between the first light-emitting element 130 and the 1-2 trench T1b, the first light-emitting element 130 attached on the pickup head 330 at a position at which transfer is not to be performed may be prevented from colliding with the display panel during transfer of the light-emitting elements.

A length TT of each of the first trenches T1a and T1b in the first direction may be configured to be shorter than each of the lengths BT1, BT2, and BT3 of the banks BNK in the first direction.

A gap BTD may be formed between a respective end of the first trenches T1a and T1b and a respective end of the banks BNK1, BNK2, and BNK3. The gap BTD between the respective end of the first trenches T1a and T1b and the respective end of the banks BNK1, BNK2, and BNK3 in the first direction may be formed to be shorter than the respective length TT of the first trenches T1a and T1b in the first direction. However, the present disclosure is not limited thereto, and as illustrated in FIG. 11B, the first trenches T1a and T1b may have a greater length TT in the first direction than that in FIG. 11A, such that the first trenches T1a and T1b are disposed between the banks BNK1, BNK2, and BNK3 without the gap BTD in the first direction.

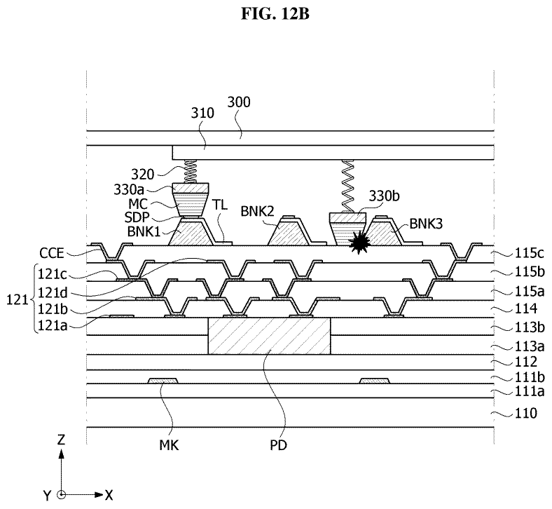

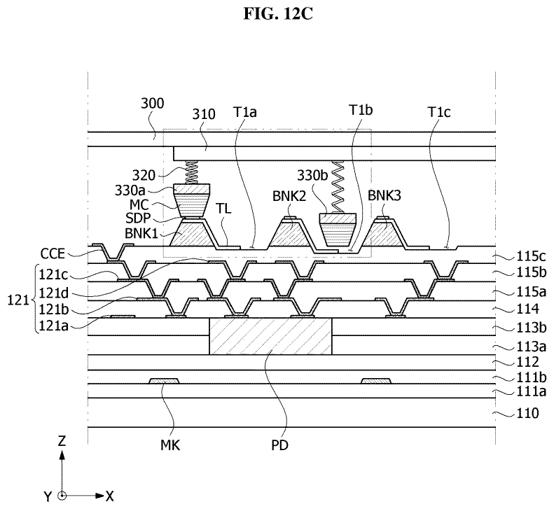

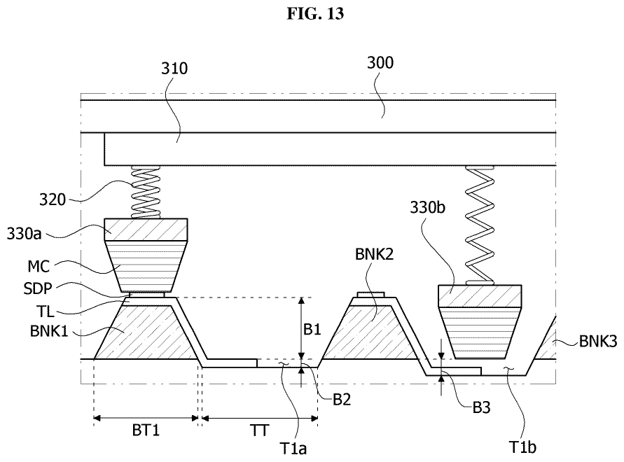

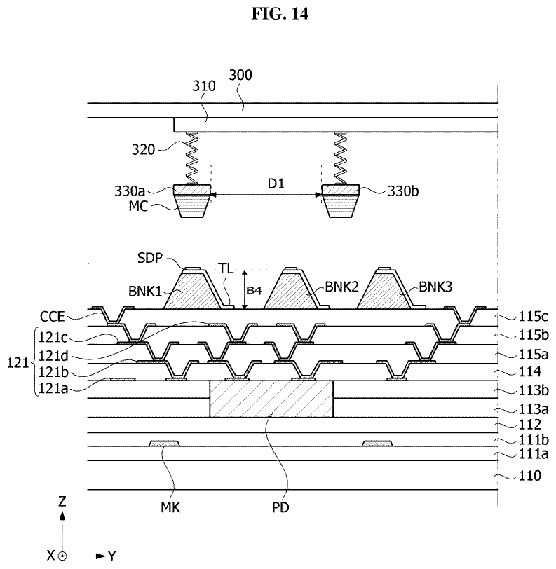

FIGS. 12A to 12C are cross-sectional views illustrating a process of transferring light-emitting elements of the display device according to an embodiment of the present disclosure. FIG. 13 is an enlarged cross-sectional view of a portion of FIG. 12C according to an embodiment of the present disclosure. FIG. 14 is a cross-sectional view illustrating a process of transferring light-emitting elements of the display device according to another embodiment of the present disclosure.

Referring to FIGS. 12A to 12C, a first buffer layer 111a and a second buffer layer 111b may be disposed on a support substrate 110.

The first buffer layer 111a and the second buffer layer 111b may be disposed in the display area AA, the first non-display area NA1, and the second non-display area NA2. The first buffer layer 111a and the second buffer layer 111b may reduce the penetration of moisture or impurities through the support substrate 110. The first buffer layer 111a and the second buffer layer 111b may be formed of an inorganic insulating material. For example, the first buffer layer 111a and the second buffer layer 111b may each be formed as a single layer or multiple layers of silicon oxide (SiOx) or silicon nitride (SiNx), but the embodiments of the present disclosure are not limited thereto.

For example, some of the first buffer layer 111a and the second buffer layer 111b located in a bending area BA may be removed. An upper surface of the support substrate 110 located in the bending area BA may be exposed from the first buffer layer 111a and the second buffer layer 111b. The first buffer layer 111a and the second buffer layer 111b, which are formed of an inorganic insulating material, may be removed from the bending area BA to minimize cracks that may occur in the first buffer layer 111a and the second buffer layer 111b during bending.

A plurality of alignment keys MK may be disposed between the first buffer layer 111a and the second buffer layer 111b. The plurality of alignment keys MK may be configured to identify the position of the pixel driving circuit PD during the manufacturing process of the display device 1000.

An adhesive layer 112 may be disposed on the second buffer layer 111b. The adhesive layer 112 may be disposed in the display area AA, the first non-display area NA1, the bending area BA, and the second non-display area NA2. In another example, at least a portion of the adhesive layer 112 may be removed from the non-display area NA including the bending area BA. For example, the adhesive layer 112 may be formed of any one of an adhesive polymer, an epoxy resin, an ultraviolet (UV)-curable resin, a polyimide-based material, an acrylate-based material, a urethane-based material, and polydimethylsiloxane (PDMS), but the embodiments of the present disclosure are not limited thereto.

In the display area AA, the pixel driving circuit PD may be disposed on the adhesive layer 112. When the pixel driving circuit PD is implemented as a micro driver, the micro driver may be mounted on the adhesive layer 112 through a transfer process. The pixel driving circuit PD disposed on the adhesive layer 112 may be manufactured using a MOSFET fabrication process on a semiconductor substrate and then transferred. The plurality of alignment keys MK may be configured during the manufacturing process of the display device 1000 to identify the position of the pixel driving circuit PD, thereby enabling accurate alignment of the pixel driving circuit PD during transfer. For example, four alignment keys MK may be disposed for one pixel driving circuit PD so that each pixel driving circuit PD can be aligned at a position to be mounted. However, the embodiments of the present disclosure are not limited thereto, and the position of the pixel driving circuit PD may be identified and the pixel driving circuit PD may be transferred using two or one alignment key MK.

A first protective layer 113a and a second protective layer 113b may be disposed on the adhesive layer 112 and the pixel driving circuit PD. The first protective layer 113a and the second protective layer 113b may be disposed to surround side surfaces of the pixel driving circuit PD, but the embodiments of the present disclosure are not limited thereto. For example, the second protective layer 113b may be disposed to cover at least a portion of an upper surface of the pixel driving circuit PD. For example, at least one of the first protective layer 113a and the second protective layer 113b disposed in the bending area BA may be omitted. For example, the first protective layer 113a may be entirely disposed in the display area AA and the non-display area NA, and the second protective layer 113b may be partially disposed in the display area AA, the first non-display area NA1, and the second non-display area NA2. For example, a portion of the second protective layer 113b in the bending area BA may be removed. However, the embodiments of the present disclosure are not limited thereto.

The first protective layer 113a and the second protective layer 113b may be formed of an organic insulating material, but the embodiments of the present disclosure are not limited thereto. For example, the first protective layer 113a and the second protective layer 113b may be formed of a photoresist, a polyimide (PI)-based material, a photo acrylic-based material, or the like, but the embodiments of the present disclosure are not limited thereto. For example, the first protective layer 113a and the second protective layer 113b may each be an overcoating layer or an insulating layer, but the embodiments of the present disclosure are not limited thereto.

According to the present disclosure, a plurality of first connection lines 121 may be disposed on the second protective layer 113b in the display area AA. The plurality of first connection lines 121 may be lines for electrically connecting the pixel driving circuit PD to other components. For example, the pixel driving circuit PD may be electrically connected to the plurality of signal lines TL, the plurality of contact electrodes CCE, and the like through the plurality of first connection lines 121. For example, the plurality of first connection lines 121 may include a 1-1 connection line 121a, a 1-2 connection line 121b, a 1-3 connection line 121c, and a 1-4 connection line 121d, but the embodiments of the present disclosure are not limited thereto.

For example, a plurality of 1-1 connection lines 121a may be disposed on the second protective layer 113b. The plurality of 1-1 connection lines 121a may be electrically connected to the pixel driving circuit PD. The plurality of 1-1 connection lines 121a may transmit a voltage output from the pixel driving circuit PD to the first electrode CE1 or the second electrode CE2.

For example, a third protective layer 114 may be disposed on the second protective layer 113b. The third protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be formed of an organic insulating material. For example, the third protective layer 114 may be formed of a photoresist, a polyimide (PI)-based material, a photo acrylic-based material, or the like, but the embodiments of the present disclosure are not limited thereto. For example, the first protective layer 113a, the second protective layer 113b, and the third protective layer 114 may be formed of the same material, but the embodiments of the present disclosure are not limited thereto.

A plurality of 1-2 connection lines 121b may be disposed on the third protective layer 114. The plurality of 1-2 connection lines 121b may be connected to or directly connected to the pixel driving circuit PD. For example, some of the 1-2 connection lines 121b may be directly connected to the pixel driving circuit PD through contact holes of the third protective layer 114. Another part of the 1-2 connection lines 121b may be electrically connected to the 1-1 connection line 121a through contact holes of the third protective layer 114. However, the embodiments of the present disclosure are not limited thereto. The voltage output from the pixel driving circuit PD may be transmitted to the first electrode CEL or the second electrode CE2 through the plurality of 1-2 connection lines 121b and other connection lines.

A first insulating layer 115a may be disposed on the plurality of 1-2 connection lines 121b. The first insulating layer 115a may be entirely disposed in the display area AA and the non-display area NA, but the embodiments of the present disclosure are not limited thereto. The first insulating layer 115a may be formed of an organic insulating material, but the embodiments of the present disclosure are not limited thereto. For example, the first insulating layer 115a may be formed of a photoresist, a polyimide (PI)-based material, a photo acrylic-based materials or the like, but the embodiments of the present disclosure are not limited thereto.

A plurality of 1-3 connection lines 121c may be disposed on the first insulating layer 115a. The plurality of 1-3 connection lines 121c may be electrically connected to the plurality of 1-2 connection lines 121b. For example, the 1-3 connection lines 121c may be electrically connected to the 1-2 connection lines 121b through contact holes of the first insulating layer 115a.

A second insulating layer 115b may be disposed on the plurality of 1-3 connection lines 121c. The second insulating layer 115b may be disposed in the remaining area excluding the bending area BA, but the embodiments of the present disclosure are not limited thereto. The second insulating layer 115b may be disposed in the display area AA, the first non-display area NA1, and the second non-display area NA2, but the embodiments of the present disclosure are not limited thereto. For example, a portion of the second insulating layer 115b disposed in the bending area BA may be removed. The second insulating layer 115b may be formed of an organic insulating material, but the embodiments of the present disclosure are not limited thereto. For example, the second insulating layer 115b may be formed of a photoresist, a polyimide (PI)-based material, a photo acrylic-based material, or the like, but the embodiments of the present disclosure are not limited thereto.

A plurality of 1-4 connection lines 121d may be disposed on the second insulating layer 115b. The plurality of 1-4 connection lines 121d may be electrically connected to the plurality of 1-3 connection lines 121c. For example, the 1-4 connection lines 121d may be electrically connected to the 1-3 connection lines 121c through contact holes of the second insulating layer 115b.

In the display area AA, a plurality of banks BNK may be disposed on the third insulating layer 115c. The plurality of banks BNK may be disposed to overlap the plurality of sub-pixels, respectively. At least one or more light-emitting elements ED of the same type may be disposed on each of the plurality of banks BNK.

A plurality of signal lines TL may be disposed on the third insulating layer 115c in the display area AA. The plurality of signal lines TL may be disposed in an area between the plurality of banks BNK. For example, the plurality of signal lines TL may be disposed adjacent to any one of the plurality of banks BNK.

A plurality of contact electrodes CCE may be disposed on the third insulating layer 115c in the display area AA. The plurality of contact electrodes CCE may supply a cathode voltage output from the pixel driving circuit PD to the second electrode CE2.

The first electrode CE1 may be disposed on the bank BNK. For example, the first electrode CE1 may be disposed to extend toward an upper portion of the bank BNK from the adjacent signal line TL. The first electrode CE1 may be disposed on upper and side surfaces of the bank BNK. For example, the first electrode CE1 may be disposed to extend from the signal line TL on an upper surface of the third insulating layer 115c to the side and upper surfaces of the bank BNK.

Among a plurality of conductive layers forming the first electrode CE1 disposed on the bank BNK, some conductive layers with high reflectivity may be configured as alignment keys and/or reflectors for aligning the light-emitting element ED.

After the elements MC, which have undergone a manufacturing process on a wafer, are picked up by the pickup heads 330 of the transfer substrate 300 and transported, the elements MC may be transferred onto solder patterns SDP of the banks BNK by using some conductive layers as alignment keys for aligning the light-emitting element ED.

Various defects may occur during the process of transferring a plurality of elements MC having a micro size onto the solder patterns SDP of the banks BNK from the wafer. For example, in some sub-pixels, a transfer defect may occur in which the element MC is not transferred, and in other sub-pixels, a defect may occur in which the element MC is transferred out of an intended position due to misalignment.

In particular, when transferring the elements MC onto the banks BNK using a multi-place process, a larger number of elements MC are picked up by a plurality of pickup heads 330 in a single pickup operation from the wafer 1001 than the number of elements MC to be transferred in a single transfer operation, in order to enable multiple transfers from one pickup.

Accordingly, the first spacing D1 between adjacent pickup heads 330 may be formed to be smaller than a spacing between the banks BNK on which transfer is to be performed. For example, when the transfer is performed such that the first spacing D1 between a first pickup head 330a picking up the element MC to be transferred onto the first bank BNK1 and an adjacent second pickup head 330b is formed to be smaller than the spacing between the first banks BNK1, a defect may occur during the transfer process, as illustrated in FIG. 12B, in which the element MC attached to the second pickup head 330b, which is not intended to be transferred at that time, collides with the third insulating layer 115c of the display panel 100 due to excessive compressive force generated between the elastic member and the third insulating layer 115c.

To prevent such a collision, as illustrated in FIG. 12C, the 1-1 trench T1a may be disposed between the first bank BNK1 and the second bank BNK2, the 1-2 trench T1b may be disposed between the second bank BNK2 and the third bank BNK3, and the 1-3 trench T1c may be disposed between the third bank BNK3 and the first bank BNK1 of the adjacent pixel PX by etching the third insulating layer 115c.

Accordingly, in some areas, a thickness of the third insulating layer 115c between adjacent banks BNK1, BNK2, and BNK3 may be configured to be smaller than a thickness of the third insulating layer 115c below the banks BNK1, BNK2, and BNK3. For convenience of description, all layers below the banks BNK1, BNK2 and BNK3 may be collectively referred to as a substrate.

By disposing the first trenches T1a and T1b between the banks BNK1, BNK2, and BNK3, it is possible to prevent the element MC, which is not intended to be transferred during the transfer process, such as the element MC attached to the second pickup head 330b, from colliding with the third insulating layer 115c due to excessive compressive force.

Referring to FIG. 13, each of a thickness B2 of the 1-1 trench T1a and a thickness B3 of the 1-2 trench T1b may be configured to be smaller than a thickness B1 of the bank BNK. In addition, the thickness B2 of the 1-1 trench T1a and the thickness B3 of the 1-2 trench T1b may be configured to be different from each other. For example, the thickness B3 of the 1-2 trench T1b may be configured to be greater than the thickness B2 of the 1-1 trench T1a. However, the present disclosure is not limited thereto. Besides, although not shown in the drawing, a thickness of each of the second trenches T2 may be configured to be smaller than a thickness B1 of the bank BNK.

The thickness B2 of the 1-1 trench T1a may be configured to be equal to a thickness of the signal line TL disposed on the 1-1 trench T1a. The thickness B3 of the 1-2 trench T1b may be configured to be greater than a thickness of the signal line TL disposed on the 1-2 trench T1b.

By configuring the thickness B3 of the 1-2 trench T1b to be greater than the thickness B2 of the 1-1 trench T1a, it is possible to prevent a collision between the third insulating layer 115c and the element MC during the transfer of the first light-emitting element 130, which is the largest among the plurality of light-emitting elements 130, 140, and 150. Alternatively, as shown in FIG. 14, a thickness B4 of each of the banks BNK1, BNK2, and BNK3, on which the plurality of light-emitting elements 130, 140, and 150 are disposed, may be configured to be greater than the thickness B1 of the conventional bank BNK, so as to prevent the light-emitting element MC, which is attached to the second pickup head 330b and subjected to excessive compressive force, from colliding with the third insulating layer 115c. For example, by additionally configuring the thickness B4 of each of the banks BNK1, BNK2, and BNK3 to correspond to the sum of the thickness B1 of the conventional bank BNK and the thickness B3 of the 1-2 trench T1b, it is possible to prevent the element MC from colliding with the third insulating layer 115c.

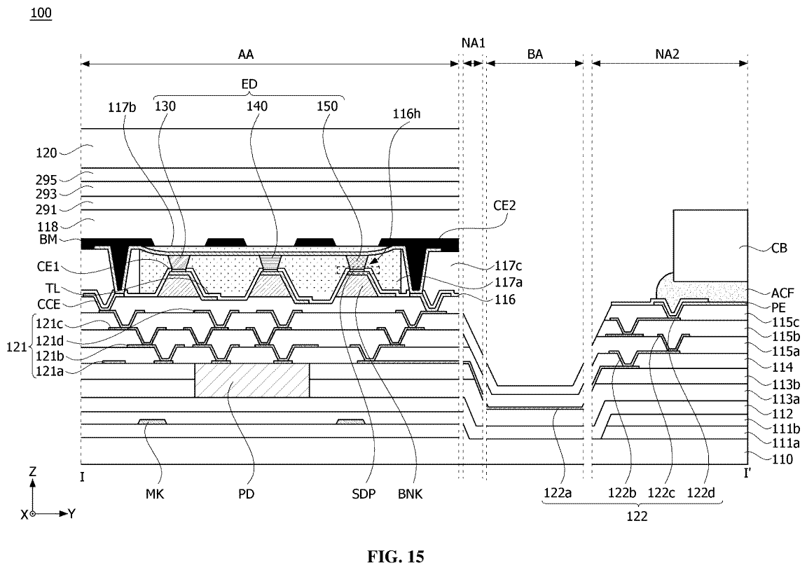

FIG. 15 is a cross-sectional view of the display device according to an embodiment of the present disclosure, taken along line I-I′ of FIG. 3. FIG. 16 is a cross-sectional view illustrating the sub-pixel including the light-emitting element disposed in the display area AA according to an embodiment of the present disclosure.

FIG. 15 is a cross-sectional view of the display area AA, the first non-display area NA1, the bending area BA, and the second non-display area NA2.

Referring to FIG. 15, a passivation layer 116 may be disposed on the plurality of signal lines TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A portion of the passivation layer 116 disposed in the bending area BA may be removed. In the second non-display area NA2, a portion of the passivation layer 116 covering the plurality of pad electrodes PE may be removed. The passivation layer 116 may be disposed to cover remaining areas except for the bending area BA, the area in which the plurality of pad electrodes PE and the solder pattern SDP are disposed, thereby reducing the penetration of moisture or impurities into the light-emitting element ED. For example, the passivation layer 116 may be formed as a single layer or multiple layers of silicon oxide (SiOx) or silicon nitride (SiNx), but the embodiments of the present disclosure are not limited thereto. For example, the passivation layer 116 may be a protective layer, an insulating layer, or the like, but the embodiments of the present disclosure are not limited thereto. For example, the passivation layer 116 may include an opening 116h that exposes the solder pattern SDP.

In each of the plurality of sub-pixels, the light-emitting element ED may be disposed on the solder pattern SDP. In the first sub-pixel SP1, the first light-emitting element 130 may be disposed. In the second sub-pixel SP2, the second light-emitting element 140 may be disposed. In the third sub-pixel SP3, the third light-emitting element 150 may be disposed.

The light-emitting element ED may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the embodiments of the present disclosure are not limited thereto.

The first electrode CE1 may be formed of a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may each be formed of titanium (Ti), molybdenum (Mo), aluminum (Al), titanium (Ti), or indium tin oxide (ITO), but the embodiments of the present disclosure are not limited thereto.

According to the present disclosure, among the plurality of conductive layers forming the first electrode CE1, some conductive layers with high reflectivity may be configured as alignment keys and/or reflectors for the alignment of the light-emitting element ED. For example, among the plurality of conductive layers of the first electrode CE1, the second conductive layer CE1b may include a reflective material. For example, the second conductive layer CE1b may include aluminum (Al), but the embodiments of the present disclosure are not limited thereto. Accordingly, the second conductive layer CE1b may be configured as a reflector. Further, due to the high reflectivity of the second conductive layer CE1b, identification may be facilitated in the manufacturing process, thereby allowing the position or transfer position of the light-emitting element ED to be aligned based on the second conductive layer CE1b.

For example, to configure the second conductive layer CE1b as a reflector, the third conductive layer CE1c and the fourth conductive layer CE1d covering the second conductive layer CE1b may be partially removed or etched. For example, some of the third conductive layer CE1c and the fourth conductive layer CE1d disposed on the banks BNK may be removed or etched to expose an upper surface of the second conductive layer CE1b. For example, in each of the third conductive layer CE1c and the fourth conductive layer CE1d, a central portion on which the solder pattern SDP is disposed and edge portions may be retained, whereas the remaining portions may be removed. For example, the edge portions of each of the third conductive layer CE1c, which is formed of titanium (Ti), and the fourth conductive layer CE1d, which is formed of indium tin oxide (ITO), may not be etched. Accordingly, it is possible to prevent other conductive layers of the first electrode CE1 from being corroded by a tetramethylammonium hydroxide (TMAH) solution used in the masking process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has good adhesion to the solder pattern SDP and exhibits corrosion resistance and acid resistance. However, the embodiments of the present disclosure are not limited thereto.

The first conductive layer CE1a, the second conductive layer CE1b, the third conductive layer CE1c, and the fourth conductive layer CE1d may be sequentially deposited and then patterned through a photolithography process and an etching process, but the embodiments of the present disclosure are not limited thereto.

According to the present disclosure, the signal line TL, contact electrode CCE, and pad electrode PE, which are disposed on the same layer as the first electrode CE1, may be formed as multiple layers of conductive materials, but the embodiments of the present disclosure are not limited thereto. For example, the signal line TL, the contact electrode CCE, and the pad electrode PE may be formed as multiple layers of indium tin oxide (ITO)/titanium (Ti)/aluminum (Al)/titanium (Ti), but the embodiments of the present disclosure are not limited thereto.

According to the present disclosure, the solder pattern SDP may be disposed on the first electrode CE1 in each of the plurality of sub-pixels. The solder pattern SDP may allow the light-emitting element ED to be bonded to the first electrode CE1. The first electrode CE1 and the light-emitting element ED may be electrically connected through eutectic bonding using the solder pattern SDP, but the embodiments of the present disclosure are not limited thereto. For example, when the solder pattern SDP is formed of indium (In) and the anode 134 of the light-emitting element ED is formed of gold (Au), the solder pattern SDP and the anode 134 may be bonded by applying heat and pressure during the transfer process of the light-emitting element ED. Through eutectic bonding, the light-emitting element ED may be bonded to the solder pattern SDP and the first electrode CE1 without any additional adhesive. For example, the solder pattern SDP may be formed of indium (In), tin (Sn), or an alloy thereof, but the embodiments of the present disclosure are not limited thereto. For example, the solder pattern SDP may be a bonding pad, a joining pad, or the like, but the embodiments of the present disclosure are not limited thereto.

A first optical layer 117a surrounding the plurality of light-emitting elements ED may be disposed in the display area AA. For example, the first optical layer 117a may be disposed to cover the plurality of light-emitting elements ED and the banks BNK in the areas of the plurality of sub-pixels. For example, the first optical layer 117a may cover the banks BNK, a portion of the passivation layer 116, and a space between the plurality of light-emitting elements ED. The first optical layer 117a may be disposed or may cover the spaces between the plurality of light-emitting elements ED included in one pixel PX and between the plurality of banks BNK. For example, the first optical layer 117a may extend in a first direction (X-axis direction) and may be disposed spaced apart in a second direction (Y-axis direction). For example, the first optical layer 117a may be disposed to surround the side portions of the light-emitting element ED and the bank BNK between the passivation layer 116 and the second electrode CE2, but the embodiments of the present disclosure are not limited thereto. For example, the first optical layer 117a may be a diffusion layer, a sidewall diffusion layer, or the like, but the embodiments of the present disclosure are not limited thereto.

The first optical layer 117a may include an organic insulating material in which fine particles are dispersed, but the embodiments of the present disclosure are not limited thereto. For example, the first optical layer 117a may be formed of siloxane in which fine metal particles, such as titanium dioxide (TiO₂) particles, are dispersed, but the embodiments of the present disclosure are not limited thereto. Light emitted from the plurality of light-emitting elements ED may be scattered by the fine particles dispersed in the first optical layer 117a and emitted to the outside of the display device 1000. Accordingly, the first optical layer 117a may improve the extraction efficiency of the light emitted from the plurality of light-emitting elements ED.

For example, the first optical layer 117a may be disposed in each of the plurality of pixels PX, or the first optical layer 117a may be disposed together with some of the pixels PX disposed in the same row, but the embodiments of the present disclosure are not limited thereto. For example, the first optical layer 117a may be disposed in each of the plurality of pixels PX, or the plurality of pixels PX may share one first optical layer 117a. In another example, each of the plurality of sub-pixels may separately include the first optical layer 117a, but the embodiments of the present disclosure are not limited thereto.

According to the present disclosure, a third optical layer 117c may be disposed on the passivation layer 116 in the display area AA. For example, the third optical layer 117c may be disposed to surround the first optical layer 117a. For example, the third optical layer 117c may be in contact with a side surface of the first optical layer 117a. For example, the third optical layer 117c may be disposed in the area between the plurality of pixels PX. However, the embodiments of the present disclosure are not limited thereto, and for example, the third optical layer 117c may be a diffusion layer, a diffusion layer window, a window diffusion layer, or the like, but the embodiments of the present disclosure are not limited thereto.

The third optical layer 117c may be formed of an organic insulating material, but the embodiments of the present disclosure are not limited thereto. The third optical layer 117c may be formed of the same material as the first optical layer 117a, but the embodiments of the present disclosure are not limited thereto. For example, the first optical layer 117a may include fine particles, and the third optical layer 117c may not include fine particles. For example, the third optical layer 117c may be formed of siloxane, but the embodiments of the present disclosure are not limited thereto.

For example, a thickness of the first optical layer 117a may be smaller than a thickness of the third optical layer 117c, but the embodiments of the present disclosure are not limited thereto. Accordingly, when viewed in a plan view, an area in which the first optical layer 117a is disposed may include a recessed portion that is recessed inward relative to an upper surface of the third optical layer 117c.

According to the present disclosure, the second electrode CE2 may be disposed on the first optical layer 117a and the third optical layer 117c. For example, the second electrode CE2 may be electrically connected to the plurality of contact electrodes CCE through a contact hole of the third optical layer 117c. For example, the second electrode CE2 may be disposed on the plurality of light-emitting elements ED. For example, the second electrode CE2 may include a transparent conductive oxide such as indium tin oxide (ITO) or indium zinc oxide (IZO), but the embodiments of the present disclosure are not limited thereto. For example, the second electrode CE2 may be disposed to be in contact with the cathode 135. For example, the second electrode CE2 may overlap the first optical layer 117a. For example, the second electrode CE2 may cover a plane on an outer side of the first optical layer 117a.

The second electrode CE2 may continuously extend in the first direction (X-axis direction) of the support substrate 110. Accordingly, the second electrode CE2 may be commonly connected to the plurality of pixels PX arranged in the first direction X of the support substrate 110. For example, the second electrode CE2 may be commonly connected to a plurality of pixels PX.

According to the present disclosure, the second electrode CE2 may continuously extend on the first optical layer 117a, the third optical layer 117c, and the light-emitting element ED. The area in which the first optical layer 117a is disposed may include a recessed portion that is recessed inward relative to the upper surface of the third optical layer 117c. Accordingly, since a first portion of the second electrode CE2 disposed on the first optical layer 117a is disposed along the recessed portion, the first portion of the second electrode CE2 may be disposed at a position lower than a second portion of the second electrode CE2 disposed on the third optical layer 117c.

A second optical layer 117b may be disposed on the second electrode CE2. The second optical layer 117b may be disposed to overlap the plurality of light-emitting elements ED and the first optical layer 117a. Since the second optical layer 117b is disposed on the second electrode CE2 and the plurality of light-emitting elements ED, the second optical layer 117b may improve the mura that may occur in some of the plurality of light-emitting elements ED. For example, when transferring the plurality of light-emitting elements ED onto the support substrate 110 of the display device 1000, an area in which intervals between the plurality of light-emitting elements ED are not uniform may occur due to process variations or the like. When the intervals between the plurality of light-emitting elements ED are not uniform, light emission areas of each of the plurality of light-emitting elements ED may be disposed unevenly, which may cause a user to perceive mura. Accordingly, by configuring the second optical layer 117b to uniformly diffuse light over the plurality of light-emitting elements ED, the occurrence of light emitted from some light-emitting elements ED appearing as mura can be reduced. Accordingly, the light emitted from the plurality of light-emitting elements ED is evenly diffused by the second optical layer 117b and extracted to the outside of the display device 1000, thereby improving the luminance uniformity of the display device 1000.

The second optical layer 117b may be formed of an organic insulating material in which fine particles are dispersed, but the embodiments of the present disclosure are not limited thereto. For example, the second optical layer 117b may be formed of siloxane in which fine metal particles, such as titanium dioxide (TiO₂) particles, are dispersed, but the embodiments of the present disclosure are not limited thereto. For example, the second optical layer 117b may be formed of the same material as the first optical layer 117a, but the embodiments of the present disclosure are not limited thereto. For example, the second optical layer 117b may be a diffusion layer, an upper diffusion layer, or the like, but the embodiments of the present disclosure are not limited thereto.

According to the present disclosure, light emitted from the plurality of light-emitting elements ED may be scattered by the fine particles dispersed in the second optical layer 117b and emitted to the outside of the display device 1000. The second optical layer 117b may evenly mix the light emitted from the plurality of light-emitting elements ED, thereby further improving the luminance uniformity of the display device 1000. In addition, the light extraction efficiency of the display device 1000 may be improved by the light scattered from the plurality of fine particles, thereby enabling the display device 1000 to operate at lower power.

In the display area AA, the black matrix BM may be disposed on the second electrode CE2, the first optical layer 117a, the second optical layer 117b, and the third optical layer 117c. For example, the contact hole of the third optical layer 117c may be filled with the black matrix BM. The black matrix BM is configured to cover the display area AA, and thus may reduce the color mixing of light from the plurality of sub-pixels and the reflection of external light. For example, the black matrix BM is also disposed in a contact hole in which the second electrode CE2 and the contact electrode CCE are connected, and thus may prevent light leakage between the plurality of adjacent sub-pixels.

For example, the black matrix BM may be formed of an opaque material, but the embodiments of the present disclosure are not limited thereto. For example, the black matrix BM may be an organic insulating material containing a black pigment or a black dye, but the embodiments of the present disclosure are not limited thereto.

In the display area AA, a cover layer 118 may be disposed on the black matrix BM. The cover layer 118 may protect the configuration below the cover layer 118, and for example, the cover layer 118 may be formed of an organic insulating material, but the embodiments of the present disclosure are not limited thereto. For example, the cover layer 118 may be formed of a photoresist, a polyimide (PI)-based material, a photo acrylic-based material, or the like, but the embodiments of the present disclosure are not limited thereto. For example, the cover layer 118 may be an overcoating layer, an insulating layer, or the like, but the embodiments of the present disclosure are not limited thereto.

The polarizing layer 293 may be disposed on the cover layer 118 via a first adhesive layer 291. The cover member 120 may be disposed on the polarizing layer 293 through a second adhesive layer 295. For example, the first adhesive layer 291 and the second adhesive layer 295 may include an optically clear adhesive (OCA), an optically clear resin (OCR), a pressure sensitive adhesive (PSA), or the like, but the embodiments of the present disclosure are not limited thereto.

According to the present disclosure, a plurality of second connection lines 122 may be disposed on the second protective layer 113b in the non-display area NA. The plurality of second connection lines 122 may be lines for transmitting signals, which are transmitted from the flexible circuit board (or flexible film) CB and the printed circuit board 160 (see FIG. 1) to the pad part PAD, to the pixel driving circuit PD of the display area AA. For example, the plurality of second connection lines 122 may be electrically connected to the plurality of pad electrodes PE to receive the signals output from the flexible circuit board (or flexible film) CB and the printed circuit board.

For example, the plurality of second connection lines 122 may extend from the pad part PAD toward the display area AA and may transmit signals to the lines of the display area AA. In this case, the plurality of second connection lines 122 may function as the link lines LL. The plurality of second connection lines 122 may include a 2-1 connection line 122a, a 2-2 connection line 122b, a 2-3 connection line 122c, and a 2-4 connection line 122d.

A plurality of 2-1 connection lines 122a may be disposed on the second protective layer 113b. The plurality of 2-1 connection lines 122a may be electrically connected to a plurality of 1-2 connection lines 121b through contact holes formed in the third protective layer 114 in the display area AA. The plurality of 2-1 connection lines 122a may extend from the second non-display area NA2 to the bending area BA and the first non-display area NA1. The plurality of 2-1 connection lines 122a may transmit signals, which are transmitted to the pad part PAD from the flexible circuit board (or flexible film) CB and the printed circuit board, to the pixel driving circuit PD of the display area AA.

A plurality of 2-2 connection lines 122b may be disposed on the third protective layer 114. The plurality of 2-2 connection lines 122b may be disposed in the second non-display area NA2. The 2-2 connection lines 122b may be electrically connected to the 2-1 connection lines 122a through contact holes of the third protective layer 114. Accordingly, the signals output from the flexible circuit board (or flexible film) CB and the printed circuit board may be transmitted to the 2-1 connection lines 122a through the 2-2 connection lines 122b.

The 2-3 connection line 122c may be disposed on the first insulating layer 115a. The 2-3 connection line 122c may be disposed in the second non-display area NA2. The 2-3 connection line 122c may be electrically connected to the 2-2 connection line 122b through a contact hole of the first insulating layer 115a. Accordingly, the signals output from the flexible circuit board (or flexible film) CB and the printed circuit board may be transmitted to the 2-1 connection lines 122a through the 2-3 connection line 122c and the 2-2 connection lines 122b.

The 2-4 connection line 122d may be disposed on the second insulating layer 115b. The 2-4 connection line 122d may be disposed in the second non-display area NA2. The 2-4 connection line 122d may be electrically connected to the 2-3 connection line 122c through the contact hole of the second insulating layer 115b. Accordingly, the signals output from the flexible circuit board (or flexible film) CB and the printed circuit board may be transmitted to the 2-1 connection lines 122a through the 2-4 connection line 122d, the 2-3 connection line 122c, and the 2-2 connection lines 122b.

The plurality of first connection lines 121 and the plurality of second connection lines 122 may be formed of a highly flexible conductive material or any of the various conductive materials used in the display area AA. For example, the second connection lines 122, some of which are disposed in the bending area BA, may be formed of a highly flexible conductive material such as gold (Au), silver (Ag), or aluminum (Al), but the embodiments of the present disclosure are not limited thereto. In another example, the plurality of first connection lines 121 and the plurality of second connection lines 122 may be formed of molybdenum (Mo), chromium (Cr), titanium (Ti), nickel (Ni), neodymium (Nd), copper (Cu), silver (Ag), magnesium (Mg), alloys thereof, or the like, but the embodiments of the present disclosure are not limited thereto.

A third insulating layer 115c may be disposed on the plurality of first connection lines 121 and the plurality of second connection lines 122. The third insulating layer 115c may be disposed in the remaining area excluding the bending area BA, but the embodiments of the present disclosure are not limited thereto. The third insulating layer 115c may be disposed in the display area AA, the first non-display area NA1, and the second non-display area NA2. A portion of the third insulating layer 115c in the bending area BA may be removed. The third insulating layer 115c may be formed of an organic insulating material, but the embodiments of the present disclosure are not limited thereto. For example, the third insulating layer 115c may be formed of a photoresist, a polyimide (PI)-based material, a photo acrylic-based material, or the like, but the embodiments of the present disclosure are not limited thereto.

According to the present disclosure, a plurality of pad electrodes PE may be disposed on the third insulating layer 115c in the second non-display area NA2. For example, at least some of the plurality of pad electrodes PE may be exposed from the passivation layer 116. For example, the plurality of pad electrodes PE may be electrically connected to the 2-4 connection line 122d through contact holes of the third insulating layer 115c.

An adhesive layer ACF may be disposed on the plurality of pad electrodes PE. The adhesive layer ACF may be an adhesive layer in which conductive balls are dispersed in an insulating material, but the embodiments of the present disclosure are not limited thereto. When heat or pressure is applied to the adhesive layer ACF, the conductive balls at the portions to which the heat or pressure is applied may be electrically connected, thereby exhibiting conductive properties. The adhesive layer ACF may be disposed between the plurality of pad electrodes PE and the flexible circuit board (or flexible film) CB, thereby allowing the flexible circuit board (or flexible film) CB to be attached or bonded to the plurality of pad electrodes PE. For example, the adhesive layer ACF may be an anisotropic conductive film (ACF), but the embodiments of the present disclosure are not limited thereto.

The flexible circuit board (or flexible film) CB may be disposed on the adhesive layer ACF. The flexible circuit board (or flexible film) CB may be electrically connected to the plurality of pad electrodes PE through the adhesive layer ACF. Accordingly, signals output from the flexible circuit board (or flexible film) CB and the printed circuit board may be transmitted to the pixel driving circuit PD of the display area AA through the plurality of pad electrodes PE, and the 2-4 connection line 122d, the 2-3 connection line 122c, the 2-2 connection line 122b, and the 2-1 connection line 122a.

Referring to FIG. 16, the first light-emitting element 130 may include an anode 134, a first semiconductor layer 131, an active layer 132, a second semiconductor layer 133, a cathode 135, and an encapsulation film 136, but the embodiments of the present disclosure are not limited thereto. For example, the first light-emitting element 130 may not include the encapsulation film 136.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a group III-V compound semiconductor, a group II-VI compound semiconductor, or the like and may be doped with impurities (or dopants). For example, one of the first semiconductor layer 131 and the second semiconductor layer 133 may be a semiconductor layer doped with n-type impurities, and the other may be a semiconductor layer doped with p-type impurities, but the embodiments of the present disclosure are not limited thereto. For example, one or more of the first semiconductor layer 131 and the second semiconductor layer 133 may be a layer doped with n-type or p-type impurities in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like, but the embodiments of the present disclosure are not limited thereto. For example, the n-type impurities may include silicon (Si), germanium (Ge), selenium (Se), carbon (C), tellurium (Te), tin (Sn), and the like, but the embodiments of the present disclosure are not limited thereto. For example, the p-type impurities may include magnesium (Mg), zinc (Zn), calcium (Ca), strontium (Sr), barium (Ba), beryllium (Be), and the like, but the embodiments of the present disclosure are not limited thereto.

For example, the first semiconductor layer 131 and the second semiconductor layer 133 may be a nitride semiconductor containing n-type impurities and a nitride semiconductor containing p-type impurities, respectively, but the embodiments of the present disclosure are not limited thereto. For example, the first semiconductor layer 131 may be a nitride semiconductor containing p-type impurities, and the second semiconductor layer 133 may be a nitride semiconductor containing n-type impurities, but the embodiments of the present disclosure are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may include one of a single well structure, a multi-well structure, a single quantum well structure, a multi-quantum well (MQW) structure, a quantum dot structure, and a quantum wire structure, but the embodiments of the present disclosure are not limited thereto. For example, the active layer 132 may be formed of indium gallium nitride (InGaN), gallium nitride (GaN), or the like, but the embodiments of the present disclosure are not limited thereto.

In another example, the active layer 132 may include a multi-quantum well (MQW) structure having a well layer and a barrier layer with a higher bandgap than the well layer. For example, the active layer 132 may include an InGaN well layer and an AlGaN barrier layer, but the embodiments of the present disclosure are not limited thereto.

The anode 134 may be disposed between the first semiconductor layer 131 and the solder pattern SDP. For example, the anode 134 may electrically connect the first semiconductor layer 131 and the first electrode CE1. An anode voltage output from the pixel driving circuit PD may be applied to the first semiconductor layer 131 through the signal line TL, the first electrode CE1, and the anode 134. For example, the anode 134 may be formed of a conductive material capable of eutectic bonding with the solder pattern SDP, but the embodiments of the present disclosure are not limited thereto. For example, the anode 134 may be formed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present disclosure are not limited thereto.

The cathode 135 may be disposed on the second semiconductor layer 133. For example, the cathode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode 135. The cathode 135 may be formed of a transparent conductive material to allow light emitted from the light-emitting element ED to be directed upward, but the embodiments of the present disclosure are not limited thereto. For example, the cathode 135 may be formed of a material such as indium tin oxide (ITO), indium zinc oxide (IZO), or indium gallium zinc oxide (IGZO), but the embodiments of the present disclosure are not limited thereto.

The encapsulation film 136 may be disposed on at least some of the first semiconductor layer 131, the active layer 132, the second semiconductor layer 133, the anode 134, and the cathode 135. For example, the encapsulation film 136 may surround at least some of the first semiconductor layer 131, the active layer 132, the second semiconductor layer 133, the anode 134, and the cathode 135.

For example, the encapsulation film 136 may protect the first semiconductor layer 131, the active layer 132, and the second semiconductor layer 133. For example, the encapsulation film 136 may be disposed on the side surfaces of the first semiconductor layer 131, the active layer 132, and the second semiconductor layer 133.

For example, the encapsulation film 136 may be disposed on at least a portion of each of the anode 134 and the cathode 135, for example, on an edge portion (or one side) of the anode 134 and an edge portion (or one side) of the cathode 135. At least a portion of the anode 134 may be exposed from the encapsulation film 136, thereby allowing the anode 134 to be connected to the solder pattern SDP. For example, at least a portion of the cathode 135 may be exposed from the encapsulation film 136, thereby allowing the cathode 135 to be connected to the second electrode CE2. For example, the encapsulation film 136 may be formed of an insulating material such as silicon nitride (SiNx) or silicon oxide (SiOx), but the embodiments of the present disclosure are not limited thereto.

In another example, the encapsulation film 136 may have a structure in which a reflective material is dispersed in a resin layer, but the embodiments of the present disclosure are not limited thereto. For example, the encapsulation film 136 may be fabricated as a reflector with various structures, but the embodiments of the present disclosure are not limited thereto. Light emitted from the active layer 132 may be reflected upward by the encapsulation film 136, thereby enhancing light extraction efficiency. For example, the encapsulation film 136 may be a reflective layer, but the embodiments of the present disclosure are not limited thereto.

According to the present disclosure, the light-emitting element ED has been described as having a vertical structure, but the embodiments of the present disclosure are not limited thereto. For example, the light-emitting element ED may have a lateral structure or a flip chip structure.

Although the first light-emitting element 130 has been described, the second light-emitting element 140 and the third light-emitting element 150 may have substantially the same structure as the first light-emitting element 130. For example, the second light-emitting element 140 and the third light-emitting element 150 may have substantially the same structure as the first semiconductor layer 131, the active layer 132, the second semiconductor layer 133, the anode 134, the cathode 135, and the encapsulation film 136 of the first light-emitting element 130.

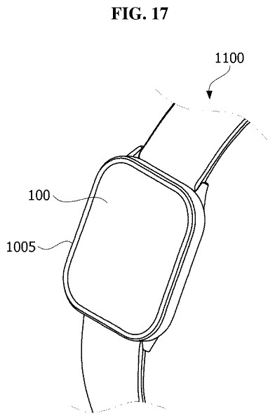

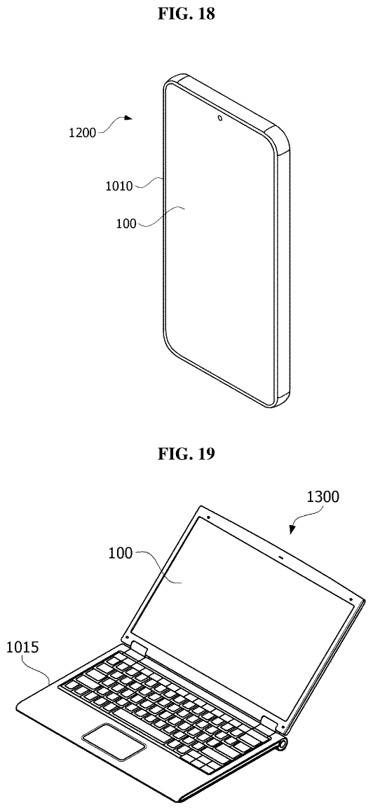

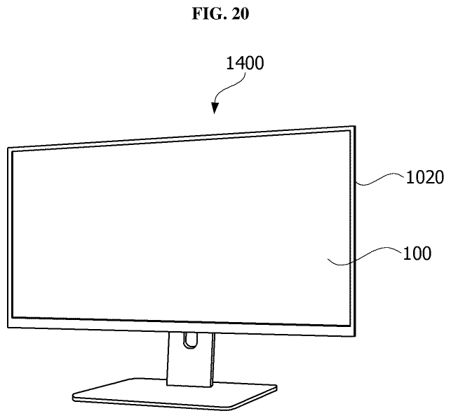

FIGS. 17 to 20 are views illustrating devices to which the display device according to embodiments of the present disclosure is applied.

Referring to FIGS. 17 to 20, a display device 1000 according to the embodiments of the present disclosure may be included in various devices or electronic devices. For example, referring to FIGS. 17 to 20, the various electronic devices may include a wearable device 1100, a mobile device 1200, a laptop computer 1300, and a monitor or TV 1400, but the embodiments of the present disclosure are not limited thereto.

The wearable device 1100, the mobile device 1200, the laptop computer 1300, and the monitor or TV 1400 may include case parts 1005, 1010, 1015, and 1020, respectively, and may each include the display panel 100 and the display device 1000 according to the embodiments of the present disclosure described above.

For example, the display device according to the embodiment of the present disclosure may be applied to mobile devices, video phones, smart watches, watch phones, wearable devices, foldable devices, rollable devices, bendable devices, flexible devices, curved devices, sliding devices, variable devices, electronic organizers, e-books, portable multimedia players (PMPs), personal digital assistants (PDAs), MP3 players, mobile medical devices, desktop personal computers (PCs) s, laptop PCs, netbook computers, workstations, navigation devices, vehicle display devices, theater display devices, televisions, wallpaper devices, signage devices, gaming devices, laptops, monitors, cameras, camcorders, household appliances, and the like.

The display panel and the method of manufacturing the same according to one or more embodiments of the present disclosure may be described as follows.

A display panel according to an embodiment of the present disclosure includes a substrate, a plurality of first banks, a plurality of second banks, and a plurality of third banks disposed on the substrate and spaced apart from each other, a plurality of first light-emitting elements respectively disposed on the first banks and configured to emit light in a first wavelength band, a plurality of second light-emitting elements respectively disposed on the second banks and configured to emit light in a second wavelength band, and a plurality of third light-emitting elements respectively disposed on the third banks and configured to emit light in a third wavelength band, wherein, in at least a partial area of the substrate, a thickness of the substrate between the adjacent banks among the plurality of first banks, the plurality of second banks, and the plurality of third banks is smaller than a thickness of the substrate below the adjacent banks.

The substrate of the display panel according to an embodiment of the present disclosure may include a support substrate, a buffer layer disposed on the support substrate, and a plurality of insulating layers disposed on the buffer layer, wherein the plurality of first banks, the plurality of second banks, and the plurality of third banks are disposed on the plurality of insulating layers.

The insulating layers of the display panel according to the embodiment of the present disclosure may include a trench disposed between the adjacent banks, in at least partial area of the substrate.

The trench of the display panel according to the embodiment of the present disclosure may include at least one of a first trench disposed along a straight line parallel to a first direction on a plane of the display panel, and a second trench disposed along a straight line parallel to a second direction orthogonal to the first direction on the plane of the display panel, and the trench may have a thickness smaller than a thickness of the support substrate, wherein the first direction is an arrange direction of the plurality of first light-emitting elements, the plurality of second light-emitting elements and the plurality of third light-emitting elements.

The trench of the display panel according to the embodiment of the present disclosure may include a plurality of first trenches disposed between the adjacent banks in the first direction, and a plurality of second trenches disposed between the adjacent banks in the second direction.

Each of the first trenches of the display panel according to the embodiment of the present disclosure may have a first length smaller than a length of each of the adjacent banks in the first direction, a second length greater than or equal to a length of each of the adjacent banks in the second direction, and a depth in a third direction, and the first trenches may be orthogonal to the second trenches.

Each of the second trenches of the display panel according to the embodiment of the present disclosure may have a first length greater than a length of each of the adjacent banks in the first direction, a second length smaller than a length of each of the adjacent banks in the second direction, and a depth in a third direction, and the second trenches may be orthogonal to the first trenches.

The first trenches and the second trenches of the display panel according to the embodiment of the present disclosure may each have a thickness smaller than a thickness of each of the adjacent banks in a third direction.

The first trenches of the display panel according to the embodiment of the present disclosure may have widths that are different depending on the light-emitting elements disposed on the adjacent banks.

At least one of the first light-emitting element, the second light-emitting element, and the third light-emitting element of the display panel according to the embodiment of the present disclosure may have a size different from that of another light-emitting element.

The first light-emitting element of the display panel according to the embodiment of the present disclosure may have a size greater than a size of each of the second light-emitting element and the third light-emitting element.

Sizes of the second light-emitting element and the third light-emitting element of the display panel according to the embodiment of the present disclosure may be substantially the same.

Each of the first trenches disposed between the first banks and the second banks of the display panel according to the embodiment of the present disclosure may have a thickness smaller than a thickness of each of the first trenches disposed between the second banks and the third banks.

Each of the first light-emitting element, the second light-emitting element, and the third light-emitting element of the display panel according to the embodiment of the present disclosure, in one pixel, may include a main light-emitting element and a redundancy light-emitting element configured to emit light at the same wavelength as the main light-emitting element.

The main light-emitting element and the redundancy light-emitting element of the display panel according to the embodiment of the present disclosure may be disposed on the same bank.

Signal lines respectively electrically connected to the first light-emitting element, the second light-emitting element, and the third light-emitting element of the display panel according to the embodiment of the present disclosure may be disposed on the first trenches.

In the corresponding trench of the display panel according to the embodiment of the present disclosure, each of the signal lines has a thickness that is smaller than or equal to a depth of each of the first trenches.

Each of the first light-emitting elements, the second light-emitting elements and the third light-emitting elements of the display panel according to the embodiment of the present disclosure may include an anode, a first semiconductor layer disposed on the anode, an active layer disposed on the first semiconductor layer, a second semiconductor layer disposed on the active layer, and a cathode disposed on the second semiconductor layer.

Each of the first light-emitting elements, the second light-emitting elements and the third light-emitting elements of the display panel according to the embodiment of the present disclosure may have a vertical structure.

The display panel according to the embodiment of the present disclosure may further include a solder pattern disposed between the anode and a first electrode.

The first electrode and the anode may be electrically connected to each other by eutectic bonding using the solder pattern.

Each of the first light-emitting elements, the second light-emitting elements and the third light-emitting elements of the display panel according to the embodiment of the present disclosure may be a micro light-emitting diode.

Each of the first light-emitting elements the second light-emitting elements and the third light-emitting elements according to the embodiment of the present disclosure may be an inorganic light-emitting element.

A method of manufacturing a display panel, according to an embodiment of the present disclosure includes picking up a plurality of light-emitting elements using a plurality of pickup heads of a light-emitting element transfer apparatus, transporting the pickup heads to which the light-emitting elements are attached to a substrate, and separating the light-emitting elements from the pickup heads to transfer the light-emitting elements onto a plurality of banks disposed on the substrate, wherein, in at least a partial area of the substrate, a thickness of the substrate between the adjacent banks is smaller than a thickness of the substrate below the banks.

In the method of manufacturing a display panel according to the embodiment of the present disclosure, the separating of the light-emitting elements from the pickup heads to transfer the light-emitting elements onto the banks may include attaching a plurality of first light-emitting elements that emit light in a first wavelength band to the pickup heads and simultaneously picking up the first light-emitting elements, transferring the first light-emitting elements onto the substrate by repeating, N times (where N is a positive integer greater than or equal to 2), an operation of separating some of the first light-emitting elements from the corresponding pickup heads and transferring the some first light-emitting elements onto the substrate, moving the pickup heads, and separating others of the first light-emitting elements from the corresponding pickup heads and transferring the other first light-emitting elements onto the substrate, attaching a plurality of second light-emitting elements that emit light in a second wavelength band to the pickup heads and simultaneously picking up the second light-emitting elements, transferring the second light-emitting elements onto the substrate by repeating, N times, an operation of separating some of the second light-emitting elements from the corresponding pickup heads and transferring the some second light-emitting elements onto the substrate, moving the pickup heads, and separating others of the second light-emitting elements from the corresponding pickup heads and transferring the other second light-emitting elements onto the substrate, attaching a plurality of third light-emitting elements that emit light in a third wavelength band to the pickup heads and simultaneously picking up the third light-emitting elements, and transferring the third light-emitting elements onto the substrate by repeating, N times, an operation of separating some of the third light-emitting elements from the corresponding pickup heads and transferring the some third light-emitting elements onto the substrate, moving the pickup heads, and separating others of the third light-emitting elements from the corresponding pickup heads and transferring the other third light-emitting elements onto the substrate.

In the method of manufacturing a display panel according to the embodiment of the present disclosure, a spacing between the pickup heads may be smaller than a spacing between a bank among the plurality of first banks, the plurality of second banks, and the plurality of third banks in one pixel and a corresponding bank in a pixel adjacent to the one pixel.

A display device according to the embodiment of the present disclosure may include the above display panel.

A display panel according to the embodiment of the present disclosure may include: a support substrate comprising a display area in which a plurality of pixels are disposed and a non-display area, wherein each of the plurality of pixels comprises a first subpixel, a second subpixel and a third subpixel; an insulating layer disposed on the support substrate; a plurality of first banks, a plurality of second banks, and a plurality of third banks disposed on the insulating layer, disposed in the first subpixel, the second subpixel and the third subpixel respectively, and spaced apart from each other; a first electrode, disposed in the first subpixel, the second subpixel and the third subpixel respectively, and disposed on the plurality of first banks, a plurality of second banks, and a plurality of third banks respectively; a first light-emitting element, a second light-emitting element and a third light-emitting element, disposed in the first subpixel, the second subpixel and the third subpixel respectively, disposed on the first electrode, and configured to emit light with wavelength bands corresponding to different colors; and a second electrode, disposed in the first subpixel, the second subpixel and the third subpixel respectively, and disposed on the first light-emitting element, the second light-emitting element and the third light-emitting element, wherein, in at least a partial area of the substrate, a thickness of the insulating layer between the adjacent banks among the plurality of first banks, the plurality of second banks, and the plurality of third banks is smaller than a thickness of the insulating layer below the adjacent banks.

According to the present disclosure, the proportion of defectively transferred light-emitting elements during the transfer of the light-emitting elements to a panel of a display device can be reduced, thereby ensuring reliability.

According to the present disclosure, the process of removing light-emitting elements defectively transferred during a conventional transfer process of the light-emitting elements can be eliminated, thereby reducing the overall process time.

The effects of the present disclosure are not limited to the effects mentioned above, and other effects not mentioned can be clearly understood by those skilled in the art to which the technical idea of the present disclosure pertains from the following description.

While the embodiments of the present invention have been described in detail above with reference to the accompanying drawings, the present invention is not necessarily limited to these embodiments, and various changes and modifications may be made without departing from the technical spirit of the present invention.

Accordingly, the embodiments disclosed herein are intended to illustrate and not to limit the technical ideas of the present invention, and the scope of the technical ideas of the present invention is not limited by these embodiments.

Accordingly, the above-described embodiments should be understood to be exemplary and not limiting in any aspect.

The scope of the present invention should be construed by the appended claims, and all technical ideas within the scope of their equivalents should be construed as being included in the scope of the present invention.

What is claimed is:

1. A display panel comprising:
a substrate;
a plurality of first banks, a plurality of second banks, and a plurality of third banks on the substrate and spaced apart from each other;
a plurality of first light-emitting elements respectively disposed on the plurality of first banks, the plurality of first light-emitting elements configured to emit light in a first wavelength band;
a plurality of second light-emitting elements respectively disposed on the plurality of second banks, the plurality of second light-emitting elements configured to emit light in a second wavelength band; and
a plurality of third light-emitting elements respectively disposed on the plurality of third banks, the plurality of third light-emitting elements configured to emit light in a third wavelength band,
wherein, in at least a partial area of the substrate, a thickness of the substrate between adjacent banks among the plurality of first banks, the plurality of second banks, and the plurality of third banks is smaller than a thickness of the substrate below the adjacent banks.

2. The display panel of claim 1, wherein the substrate includes:
a support substrate;
a buffer layer on the support substrate; and
a plurality of insulating layers on the buffer layer,
wherein the plurality of first banks, the plurality of second banks, and the plurality of third banks are on the plurality of insulating layers.

3. The display panel of claim 2, wherein, in at least partial area of the substrate, the plurality of insulating layers include a trench between the adjacent banks.

4. The display panel of claim 3, wherein the trench includes at least one of a first trench disposed along a straight line parallel to a first direction on a plane of the display panel and a second trench disposed along a straight line parallel to a second direction orthogonal to the first direction on the plane of the display panel,
wherein a thickness of the trench is smaller than a thickness of the support substrate,
wherein the first direction is an arrangement direction of the plurality of first light-emitting elements, the plurality of second light-emitting elements, and the plurality of third light-emitting elements.

5. The display panel of claim 4, wherein the first trench includes a plurality of first trenches and the second trench includes a plurality of second trenches,
wherein the plurality of first trenches are between the adjacent banks in the first direction;
and the plurality of second trenches are between the adjacent banks in the second direction.

6. The display panel of claim 5, wherein each of the plurality of first trenches has a first length that is smaller than a length of each of the adjacent banks in the first direction, a second length greater than or equal to a length of each of the adjacent banks in the second direction, and a depth in a third direction, and
the plurality of first trenches are orthogonal to the plurality of second trenches.

7. The display panel of claim 5, wherein each of the plurality of second trenches has a first length that is greater than a length of each of the adjacent banks in the first direction, a second length smaller than a length of each of the adjacent banks in the second direction, and a depth in a third direction, and
the plurality of second trenches are orthogonal to the plurality of first trenches.

8. The display panel of claim 5, wherein the plurality of first trenches and the plurality of second trenches each have a thickness that is smaller than a thickness of each of the adjacent banks in a third direction.

9. The display panel of claim 6, wherein the plurality of first trenches have widths that are different depending on which of the plurality of first light-emitting elements, the plurality of second light-emitting elements, and the plurality of third light-emitting elements are disposed on the adjacent banks.

10. The display panel of claim 1, wherein at least one of first light-emitting element from the plurality of first light-emitting elements, a second light-emitting element from the plurality of second light-emitting elements, and a third light-emitting element from the plurality of third light-emitting elements has a size that is different from that of another light-emitting element.

11. The display panel of claim 10, wherein the first light-emitting element has a size that is greater than a size of each of the second light-emitting element and the third light-emitting element.

12. The display panel of claim 10, wherein sizes of the second light-emitting element and the third light-emitting element are a same.

13. The display panel of claim 6, wherein each of the plurality of first trenches disposed between the plurality of first banks and the plurality of second banks has a thickness smaller than a thickness of each of the plurality of first trenches disposed between the plurality of second banks and the plurality of third banks.

14. The display panel of claim 1, wherein each of a first light-emitting element from the plurality of first light-emitting elements, a second light-emitting element from the plurality of second light-emitting elements, and a third light-emitting element from the plurality of third light-emitting elements in one pixel includes a main light-emitting element and a redundancy light-emitting element configured to emit light at a same wavelength as the main light-emitting element, wherein the main light-emitting element and the redundancy light-emitting element are on a same bank.

15. The display panel of claim 5, wherein signal lines respectively electrically connected to a first light-emitting element from the plurality of first light-emitting elements, a second light-emitting element from the plurality of second light-emitting elements, and a third light-emitting element from the plurality of third light-emitting elements are disposed on the plurality of first trenches.

16. The display panel of claim 15, wherein, in the corresponding trench, each of the signal lines has a thickness that is smaller than or equal to a depth of each of the plurality of first trenches.

17. The display panel of claim 1, wherein each of the plurality of first light-emitting elements, the plurality of second light-emitting elements, and the plurality of third light-emitting elements includes:
an anode;
a first semiconductor layer on the anode;
an active layer on the first semiconductor layer;
a second semiconductor layer on the active layer; and
a cathode on the second semiconductor layer.

18. The display panel of claim 17, wherein each of the plurality of first light-emitting elements, the plurality of second light-emitting elements, and the plurality of third light-emitting elements has a vertical structure.

19. The display panel of claim 18, further comprising:
a solder pattern between the anode and a first electrode,
wherein the first electrode and the anode are electrically connected to each other using the solder pattern.

20. The display panel of claim 1, wherein each of the plurality of first light-emitting elements, the plurality of second light-emitting elements, and the plurality of third light-emitting elements is an inorganic light-emitting element.
